(19) United States
(12) Patent Application Publication
(10) Pub. No.: US 2026/0190568 A1
(43) Pub. Date: Jul. 2, 2026

(54) DISPLAY DEVICE AND MANUFACTURING METHOD OF THE SAME

(71) Applicant: Samsung Display Co., Ltd., Yongin-si (KR)

(72) Inventor: SANGHO PARK, Yongin-si (KR)

(21) Appl. No.: 19/386,032

(22) Filed: Nov. 11, 2025

(30) Foreign Application Priority Data
Dec. 30, 2024 (KR) 10-2024-0201158

(51) Int. Cl. H10H 29/39; H10H 29/01; H10H 29/49

(52) U.S. Cl. CPC H10H 29/39; H10H 29/012; H10H 29/49

(57) ABSTRACT

A display device including a CMOS wafer and a light-emitting structure layer are provided. The light-emitting structure layer includes a first layer having a plurality of first light-emitting diodes, a second layer having a plurality of second light-emitting diodes, a third layer having a plurality of third light-emitting diodes, a first common electrode connected to one or more of the plurality of first light-emitting diodes, the plurality of second light-emitting diodes, and the plurality of third light-emitting diodes, a second common electrode connected to one or more of the rest of the plurality of first light-emitting diodes, the plurality of second light-emitting diodes, and the plurality of third light-emitting diodes, which are not connected to the first common electrode, and an electrode pattern having a mesh structure on a plane, and electrically connecting the first common electrode and the second common electrode.

### CROSS-REFERENCE TO RELATED APPLICATION

This application claims priority to and the benefit of Korean Patent Application No. 10-2024-0201158, filed on Dec. 30, 2024, in the Korean Intellectual Property Office, the entire disclosure of which is incorporated by reference herein.

### BACKGROUND

### 1. Field

The present disclosure herein relates to a display device and a manufacturing method of the same, and more particularly, to a display device including a Complementary Metal-Oxide-Semiconductor (CMOS) wafer and a light-emitting diode, and a manufacturing method of the same.

### 2. Description of the Related Art

An electronic apparatus for providing an image to a user, such as a smartphone, a laptop computer, a navigation unit, and/or a smart television, includes a display device for displaying an image. An augmented reality apparatus, a virtual reality apparatus, and a video projection apparatus may include a micro-display device. A micro-display device may include a CMOS wafer and a light-emitting diode disposed on the CMOS wafer so as to display an image with high brightness while being driven at low power.

### SUMMARY

The present disclosure provides a display device with reduced light loss and reduced defects.

One or more embodiments of the present disclosure provide a display device including a complementary metal oxide semiconductor (CMOS) wafer and a light-emitting structure layer on the CMOS wafer. The light-emitting structure layer includes a first layer on the CMOS wafer and having a plurality of first light-emitting diodes configured to emit light of a first wavelength, a second layer on the first layer and having a plurality of second light-emitting diodes configured to emit light of a second wavelength different from the first wavelength, a third layer on the second layer and having a plurality of third light-emitting diodes configured to emit light of a third wavelength different from the first wavelength and the second wavelength, a first common electrode connected to one or more of the plurality of first light-emitting diodes, the plurality of second light-emitting diodes, and the plurality of third light-emitting diodes, a second common electrode connected to one or more of the rest of the plurality of first light-emitting diodes, the plurality of second light-emitting diodes, and the plurality of third light-emitting diodes, which are not connected to the first common electrode, and an electrode pattern having a mesh structure on a plane, and electrically connecting the first common electrode and the second common electrode.

In one or more embodiments, each of the plurality of first light-emitting diodes may include a first light-emitting structure, a first lower conductive pattern under the first light-emitting structure, and a first upper conductive pattern on the first light-emitting structure. Each of the plurality of second light-emitting diodes may include a second light-emitting structure, a second lower conductive pattern under the second light-emitting structure, and a second upper conductive pattern on the second light-emitting structure. Each of the plurality of third light-emitting diodes may include a third light-emitting structure, a third lower conductive pattern under the third light-emitting structure, and a third upper conductive pattern on the third light-emitting structure.

A planar area of the first lower conductive pattern may be greater than or equal to a planar area of the first light-emitting structure, a planar area of the second lower conductive pattern may be greater than or equal to a planar area of the second light-emitting structure, and a planar area of the third lower conductive pattern may be greater than or equal to a planar area of the third light-emitting structure.

In one or more embodiments, the first lower conductive pattern may include at least one metal, and each of the second lower conductive pattern and the third lower conductive pattern may include a transparent conductive oxide.

In one or more embodiments, the CMOS wafer may include a silicon substrate and a contact electrode on the silicon substrate.

Each of the plurality of first lower conductive patterns may be in contact with the contact electrode.

In one or more embodiments, at least a portion of each of the plurality of first light-emitting diodes may not overlap, on a plane, the plurality of second light-emitting diodes, and the plurality of third light-emitting diodes.

In one or more embodiments, the light-emitting structure layer may further include a plurality of first connection lines respectively overlapping the plurality of first light-emitting diodes and electrically connected to the plurality of first light-emitting diodes respectively, a plurality of second connection lines respectively overlapping the plurality of second light-emitting diodes and electrically connected to the plurality of second light-emitting diodes respectively, and a plurality of third connection lines respectively overlapping the plurality of third light-emitting diodes and electrically connected to the plurality of third light-emitting diodes respectively.

In one or more embodiments of the present disclosure, the display device may further include a plurality of lenses on the third layer and overlapping one or more of the plurality of first light-emitting diodes, the plurality of second light-emitting diodes, and the plurality of the third light-emitting diodes.

In one or more embodiments, a planar area of each of the plurality of second light-emitting diodes may be greater than or equal to a planar area of each of the plurality of first light-emitting diodes, and a planar area of each of the plurality of third light-emitting diodes may be greater than or equal to a planar area of each of the plurality of second light-emitting diodes.

In one or more embodiments, the number of the plurality of second light-emitting diodes may be twice the number of the plurality of first light-emitting diodes.

In one or more embodiments, the first common electrode may be on the second layer and connected to each of the plurality of first light-emitting diodes and each of the plurality of second light-emitting diodes, and the second common electrode may be on the third layer and connected to the plurality of third light-emitting diodes. The electrode pattern and a portion of the third light-emitting diode may be at the same layer.

In one or more embodiments, the light-emitting structure layer may further include a third common electrode on the third layer and connected to the plurality of third light-emitting diodes, and an additional electrode pattern having a mesh structure on a plane and within the third layer. The first common electrode may be on the first layer and connected to the plurality of first light-emitting diodes, and the second common electrode may be on the second layer and connected to the plurality of second light-emitting diodes. The electrode pattern may be within the second layer, and the additional electrode pattern may electrically connect the second common electrode and the third common electrode.

In one or more embodiments, the CMOS wafer may include a first region in which the plurality of first light-emitting diodes, the plurality of second light-emitting diodes, and the plurality of third light-emitting diodes are each located, and a second region outside the first region on a plane. Each of the first to third layers of the light-emitting structure layer may further include a plurality of dummy light-emitting diodes in the second region. The plurality of dummy light-emitting diodes may not emit light.

In one or more embodiments, the electrode pattern may include a first electrode pattern in the first region and a second electrode pattern in the second region. The first common electrode and the second common electrode may be electrically connected by the second electrode pattern.

In one or more embodiments, the first common electrode and the second common electrode may be electrically connected by the first electrode pattern.

In one or more embodiments, the light-emitting structure layer may further include an optical layer having a plurality of first sub layers having a first refractive index and a plurality of second sub layers having a second refractive index different from the first refractive index. The optical layer may be located between the first layer and the second layer or between the second layer and the third layer.

In one or more embodiments, the first layer may further include at least a first planarization layer between the plurality of first light-emitting diodes, the second layer may further include at least a second planarization layer between the plurality of second light-emitting diodes, and the third layer may further include at least a third planarization layer between the plurality of third light-emitting diodes.

In one or more embodiments of the present disclosure, an electronic apparatus includes a display device and a housing configured to accommodate the display device. The display device includes a CMOS wafer and a light-emitting structure layer on the CMOS wafer. The light-emitting structure layer includes a first layer on the CMOS wafer and having a plurality of first light-emitting diodes configured to emit light of a first wavelength, a second layer on the first layer and having a plurality of second light-emitting diodes configured to emit light of a second wavelength different from the first wavelength, a first common electrode connected to the plurality of first light-emitting diodes, a second common electrode connected to the plurality of second light-emitting diodes, and an electrode pattern electrically connecting the first common electrode and the second common electrode. Each of the plurality of first light-emitting diodes includes a first light-emitting structure, a first lower conductive pattern under the first light-emitting structure, and a first upper conductive pattern on the first light-emitting structure, and each of the plurality of second light-emitting diodes includes a second light-emitting structure, a second lower conductive pattern under the second light-emitting structure, and a second upper conductive pattern on the second light-emitting structure. The first common electrode is connected to the first upper conductive pattern, and the second common electrode is connected to the second upper conductive pattern.

In one or more embodiments of the present disclosure, a method for manufacturing a display device includes forming a first epitaxial layer on a CMOS wafer, and then forming a plurality of first light-emitting structures through patterning, forming a second epitaxial layer on the plurality of first light-emitting structures, and then forming a plurality of second light-emitting structures through patterning, forming a third epitaxial layer on the plurality of second light-emitting structures, and then forming a plurality of third light-emitting structures through patterning, forming a first common electrode electrically connected to one or more of the plurality of first light-emitting structures, the plurality of second light-emitting structures, and the plurality of third light-emitting structures, forming a second common electrode electrically connected to one or more of the rest of the plurality of first light-emitting structures, the plurality of second light-emitting structures, and the plurality of third light-emitting structures, which are not connected to the first common electrode, and forming an electrode pattern having a mesh structure on a plane, and electrically connecting the first common electrode and the second common electrode.

In one or more embodiments, the first common electrode may be electrically connected to each of the plurality of first light-emitting structures and each of the plurality of second light-emitting structures, and the second common electrode may be electrically connected to the plurality of third light-emitting structures. The forming of the first common electrode may be performed after forming the plurality of third light-emitting structures, and the forming of the second common electrode may be performed after forming the first common electrode.

In one or more embodiments, in the forming of the plurality of first light-emitting structures, a first lower conductive layer may be formed on the CMOS wafer before forming the first epitaxial layer. A plurality of first lower conductive patterns may be formed by patterning the first lower conductive layer after the forming of the plurality of first light-emitting structures. The plurality of first light-emitting structures may respectively overlap the plurality of first lower conductive patterns, and a planar area of each of the plurality of first lower conductive patterns may be greater than or equal to a planar area of each of the plurality of first light-emitting structures.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2 is a cross-sectional view of a display device according to one or more embodiments of the present disclosure;

FIGS. 3A and 3B are each a plan view of a display device according to one or more embodiments of the present disclosure;

FIG. 4 illustrates in detail a perspective view of one light-emitting diode included in a display device according to one or more embodiments;

FIG. 5 is an enlarged plan view of a portion of a display device according to one or more embodiments of the present disclosure;

FIG. 6 is an enlarged cross-sectional view of a portion of a display device according to one or more embodiments of the present disclosure;

FIGS. 7A-7C are each a plan view of some components of a display device according to one or more embodiments of the present disclosure;

FIG. 8 is an enlarged plan view of a portion of a display device according to one or more embodiments of the present disclosure;

FIG. 9 is an enlarged cross-sectional view of a portion of a display device according to one or more embodiments of the present disclosure;

FIGS. 10A-10C are each a plan view of some components of a display device according to one or more embodiments of the present disclosure;

FIG. 11 is an enlarged plan view of a portion of a display device according to one or more embodiments of the present disclosure;

FIG. 12 is an enlarged cross-sectional view of a portion of a display device according to one or more embodiments of the present disclosure;

FIGS. 13A-13C are each a plan view of some components of a display device according to one or more embodiments of the present disclosure;

FIG. 14 is an enlarged plan view of a portion of a display device according to one or more embodiments of the present disclosure;

FIG. 15 is an enlarged cross-sectional view of a portion of a display device according to one or more embodiments of the present disclosure;

FIGS. 16A-16C are each a plan view of some components of a display device according to one or more embodiments of the present disclosure;

FIG. 17 is an enlarged cross-sectional view of a portion of a display device according to one or more embodiments of the present disclosure;

FIGS. 18A-18G are cross-sectional views sequentially illustrating some steps of a manufacturing method of a display device according to one or more embodiments of the present disclosure; and

FIGS. 19A-19E are views illustrating electronic apparatuses to which a display device according to an embodiment of the present disclosure is applied.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

In this application, the wording “directly disposed on” may indicate that a layer, a film, a region, a plate, etc., are not added between one part such as a layer, a film, a region, a plate, etc., and another part. For example, the wording “directly disposed on” may indicate that two layers or two members are disposed without using an additional member such as an adhesive member therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the spirit or scope of the present disclosure. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present specification, the expression “A and/or B” indicates A, B, or A and B. In addition, the expression such as “at least one of A and B” may include A, B, or A and B.

In the present specification, the x-axis, the y-axis, and the z-axis are not limited to directions according to three axes of the rectangular coordinate system, and may be interpreted in a broader sense. For example, the x-axis, the y-axis, and the z-axis may be orthogonal to each other, but may refer to different directions that are not orthogonal to each other.

In the present specification, the term “plane” refers to when a target portion is viewed from above (e.g., when viewed in a direction perpendicular to the upper surface of a substrate), and the term “cross-sectional” refers to when a vertically cut cross-section of the target portion is viewed from the side.

In the present specification, when a first element overlaps a second element, it may mean that the first element is arranged over or below the second element and at least partially overlaps the second element in a plane.

In the present specification, when a certain embodiment may be implemented differently, a specific process order may also be performed differently from the described order. As an example, two processes that are successively described may be performed substantially concurrently (e.g., simultaneously) or performed in an order opposite to the order described.

Sizes of elements in the drawings may be exaggerated for convenience of description. For example, because sizes and thicknesses of elements in the drawings are arbitrarily illustrated for convenience of explanation, the following embodiments are not limited thereto.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

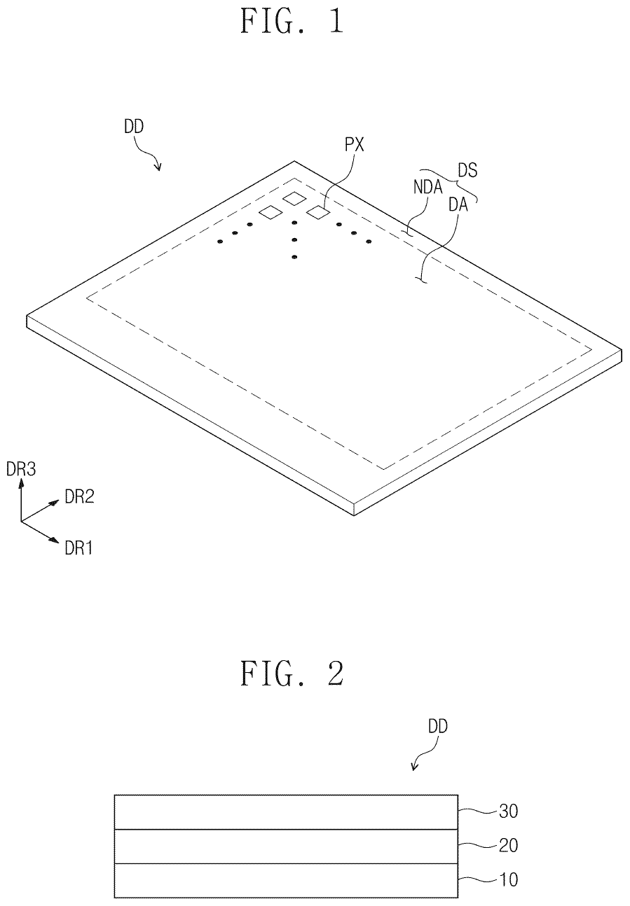

FIG. 1 is a perspective view of a display device according to one or more embodiments of the present disclosure.

Referring to FIG. 1, a display device DD according to one or more embodiments of the present disclosure may have a rectangular shape having long sides extending in a first direction DR1 and short sides extending in a second direction DR2 crossing the first direction DR1. However, the present disclosure may not be limited thereto and the display device DD may have various shapes such as a circular or a polygonal shape. Hereinafter, a direction crossing substantially perpendicularly to a plane defined by the first direction DR1 and the second direction DR2 is defined as a third direction DR3. In this specification, the wording “when seen on a plane” (e.g., in a plan view) is defined as a state seen from the third direction DR3.

An upper surface of the display device DD may be defined as a display surface DS and have a flat surface defined by the first direction DR1 and the second direction DR2. Images IM generated from the display device DD may be provided to a user through the display surface DS.

The display surface DS may include a display region DA and a non-display region NDA around the display region DA and located along an edge or a periphery of the display region DA. The display region DA displays an image, and the non-display region NDA does not display an image. The non-display region NDA may be around (e.g., may surround) the display region DA, but the present disclosure is not limited thereto, and the non-display region NDA may not be disposed on one side of the display region DA.

A plurality of pixels PX may be disposed in the display region DA. The pixels PX may be disposed in a matrix form. For example, the pixels PX may be disposed along rows and columns of a matrix. The pixels PX may each include a pixel circuit and a light-emitting diode. All of the pixels PX may generate light of the same color. In one or more embodiments of the present disclosure, the pixels PX may include a plurality of groups that generate light of different colors.

FIG. 2 is a cross-sectional view of a display device according to one or more embodiments of the present disclosure. FIG. 2 illustrates, as an example, a cross-section of the display device DD illustrated in FIG. 1.

Referring to FIG. 2, the display device DD may include a circuit element layer 10, a light-emitting structure layer 20, and a lens layer 30. However, the present disclosure is not limited thereto, and the lens layer 30 may be omitted or another functional layer may be further added in one or more embodiments of the present disclosure.

The circuit element layer 10 may include a pixel circuit. The pixel circuit may control the operation of a light-emitting diode of the light-emitting structure layer 20 to be described later. The pixel circuit may include at least one transistor. The circuit element layer 10 may include a complementary metal oxide semiconductor (CMOS) wafer. The CMOS wafer may include an nMOSFET (NMOS) and a pMOSFET (PMOS) complementarily connected to each other. In the CMOS wafer, a plurality of pixel regions are arranged in order and a pixel circuit is disposed in each pixel region.

The light-emitting structure layer 20 may include a plurality of light-emitting diodes electrically connected to the pixel circuit. The light-emitting diode is a type of a compound semiconductor and an electrically driven light-emitting diode including gallium (Ga), phosphorus (P), and/or arsenic (As) as a main semiconductor material. When a forward current is applied to a p-n junction structure, electrons and holes are combined at a junction surface and light of a specific wavelength corresponding to band gap energy may be generated.

The lens layer 30 may be disposed on the light-emitting structure layer 20 and include a plurality of lenses. The lens may be disposed overlapping at least the light-emitting diode. The lens collects light emitted from the light-emitting diode. The light collected through the lens may be transmitted through a light guiding unit.

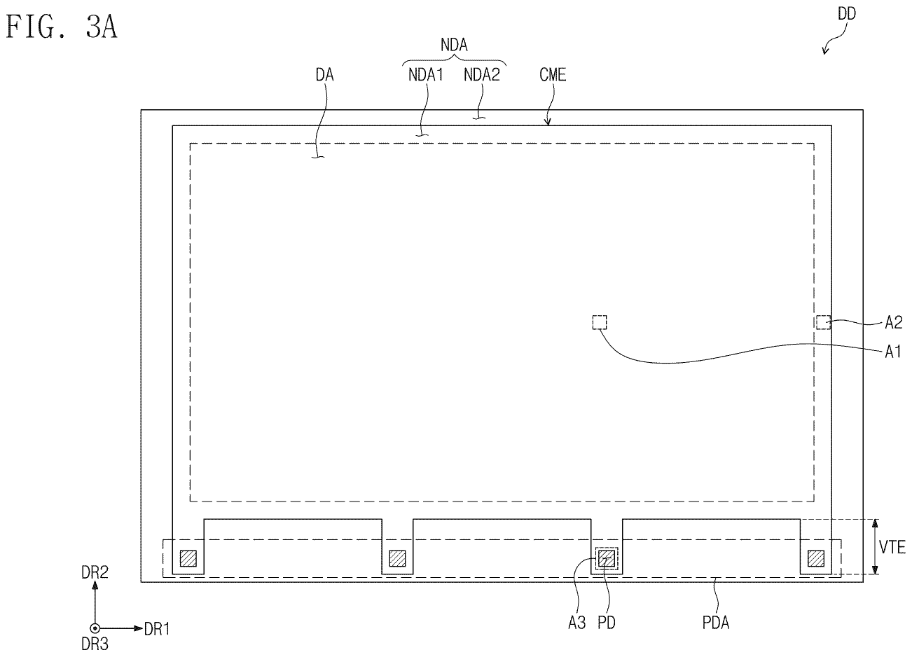

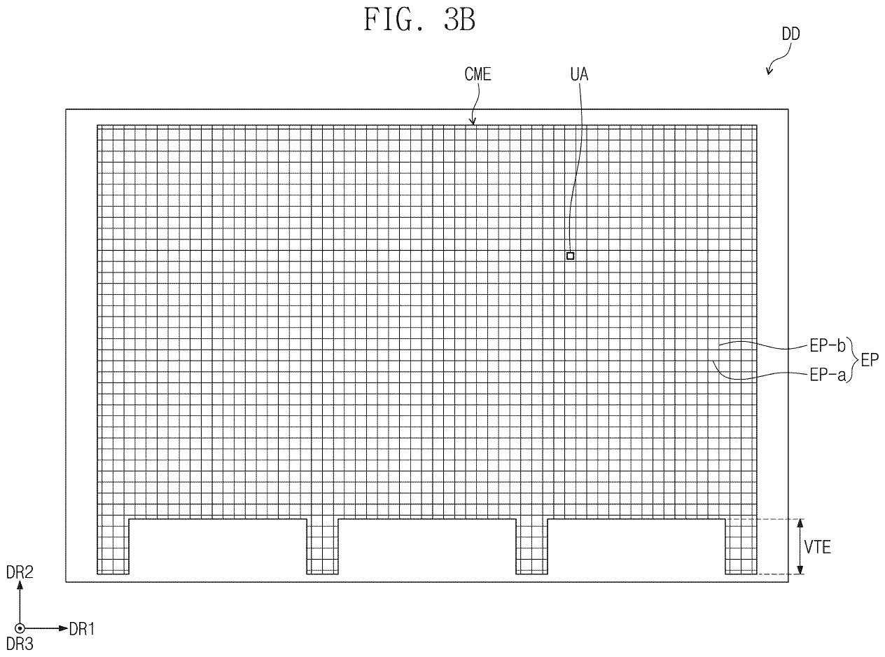

FIGS. 3A and 3B are each a plan view of a display device according to one or more embodiments of the present disclosure. FIG. 3A is a plan view in which a common electrode CME according to one or more embodiments of the present disclosure is disposed in a display region DA and a non-display region NDA of a display device DD. The display region DA and the non-display region NDA of the display device DD may be similarly applied to the circuit element layer 10, that is, the CMOS wafer, described with reference to FIG. 2. Hereinafter, the circuit element layer 10 is referred to as the CMOS wafer 10 and denoted as the same reference numeral or symbol.

The common electrode CME may cover at least the display region DA. The common electrode CME transfers, to the whole display region DA, a power voltage applied from the outside. Hereinafter, the display region DA is referred to as a first region DA and denoted as the same reference numeral or symbol.

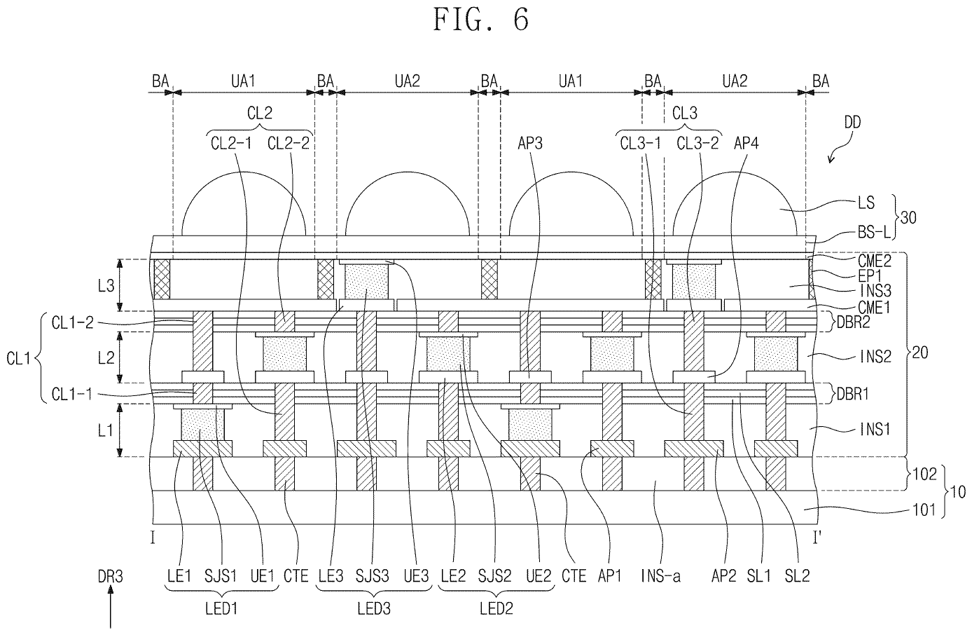

The display device DD according to one or more embodiments may include the plurality of common electrodes CME disposed on different layers. The display device DD may include a first common electrode CME1 (see FIG. 6) and a second common electrode CME2 (see FIG. 6) to be described later which are disposed on different layers, and the first common electrode CME1 (see FIG. 6) and the second common electrode CME2 (see FIG. 6) may be electrically connected to each other. This will be described in detail later.

The non-display region NDA may be separated into a plurality of regions. In this embodiment, the non-display region NDA may include a second region NDA1 and a third region NDA2.

The second region NDA1 may be disposed outside the first region DA and may be a region in which dummy light-emitting diodes to be described later are disposed. In this embodiment, the second region NDA1 may be around (e.g., may surround) the first region DA, but the present disclosure is not necessarily limited thereto. While the dummy light-emitting diodes have the same stacked structure as the light-emitting diode in the first region DA, the dummy light-emitting diodes are not electrically connected to the common electrode CME and are thus unable to operate (or emit light). The structural characteristics of the dummy light-emitting diode will be described later.

When forming the light-emitting diodes in a specific region through the same process, an outer region may have a different process condition compared to an inner region. For example, the outer region may have a thinner deposited metal layer, or have an etch rate different from that of the inner region. Resultantly, defective light-emitting diodes may be formed in the outer region, and in consideration of such events, the light-emitting diode formed in the outer region is not used as a good light-emitting diode (e.g., a light-emitting diode in a good working condition) and used as a dummy light-emitting diode. When process conditions and process efficiencies are consistent regardless of the regions, the dummy light-emitting diodes may be omitted, and thus the second region NDA1 may be omitted in one or more embodiments of the present disclosure.

The dummy light-emitting diode may not be disposed in a portion of the second region NDA1. In a portion of the second region NDA1, the common electrode CME may be disposed, but the light-emitting diode or the dummy light-emitting diode may not be disposed. For example, in a region, of the second region NDA1, adjacent to the first region DA, the dummy light-emitting diode may be disposed, and in a region, of the second region NDA1, adjacent to the third region NDA2, the dummy light-emitting diode may not be disposed.

The third region NDA2 may be a region in which the common electrode CME is not disposed. In this embodiment, the third region NDA2 may be around (e.g., may surround) the entire border of the second region NDA1, but the present disclosure is not limited thereto. A plurality of driving circuits may be disposed in the third region NDA2 of the CMOS wafer 10 (see FIG. 2). For example, a scan driver may be disposed in each of the left region and right region of the third region NDA2 with the first region DA therebetween. A data driver may be disposed in a portion of the third region NDA2 disposed at a lower side of the first region DA. In addition, an analog circuit such as a power circuit may be disposed in a portion of the third region NDA2. The scan driver, the data driver, and the analog circuit described above may be embedded in the CMOS wafer. That is, the scan driver, the data driver, and the analog circuit may include transistors formed using a similar method for the pixel circuit.

A pad region PDA in which a plurality of pad electrodes PD are disposed may be disposed at one side of the third region NDA2. The pad region PDA may correspond to a portion of the third region NDA2. A circuit board may be connected to the pad region PDA. In FIG. 3A, only four pad electrodes PD which receive a power voltage applied to the common electrode CME are illustrated, but more pad electrodes may be disposed in the pad region PDA. The pad electrodes which are not illustrated may receive a data image signal or control signals from the outside and provide the signals to the data driver.

Referring to FIG. 3A, a voltage transfer electrode VTE may be disposed in the third region NDA2. Four voltage transfer electrodes VTE corresponding to the four pad electrodes PD are illustrated. The voltage transfer electrode VTE may extend from the common electrode CME toward the pad region PDA. The voltage transfer electrode VTE and the common electrode CME may be formed through the same process, have the same stacked structure, and have an integrated shape. The voltage transfer electrode VTE and the common electrode CME may be different portions of one electrode formed through the same process.

FIG. 3B is a plan view illustrating the common electrode CME according to one or more embodiments of the present disclosure and an arrangement relationship between the voltage transfer electrode VTE and an electrode pattern EP.

The electrode pattern EP overlaps each of the common electrodes CME and the voltage transfer electrodes VTE. The electrode pattern EP is disposed under the common electrode CME and the voltage transfer electrode VTE in the third direction DR3.

The electrode pattern EP may include a plurality of first lines EP-a extending in the first direction DR1 and a plurality of second lines EP-b extending in the second direction DR2. The first lines EP-a are arranged along the second direction DR2, and the second lines EP-b are arranged along the first direction DR1.

A unit region UA may be positioned within a region defined by two most adjacent first lines EP-a from among the first lines EP-a and two most adjacent second lines EP-b from among the second lines EP-b. The unit region UA is disposed within the display region DA of FIG. 3A. FIG. 3B representatively illustrates one unit region UA. A plurality of light-emitting diodes are disposed in the unit region UA. This will be described later in detail.

A portion of the electrode pattern EP may overlap the common electrode CME, and the portion overlapping the common electrode CME may be entirely connected to the common electrode CME, thereby reducing a voltage drop which occurs in the common electrode CME. Another portion of the electrode pattern EP may overlap the voltage transfer electrode VTE, and the other portions overlapping the voltage transfer electrode VTE may be entirely connected to the voltage transfer electrode VTE, thereby lowering the resistance of a voltage transfer path between the pad electrode PD (see FIG. 3A) and the common electrode CME and the voltage transfer electrode VTE. The electrode pattern EP may be formed through the same process regardless of the regions and may have an integrated shape.

The electrode pattern EP may electrically connect the aforementioned first common electrode CME1 (see FIG. 6) and the second common electrode CME2 (see FIG. 6) disposed on different layers. This will be described in detail later.

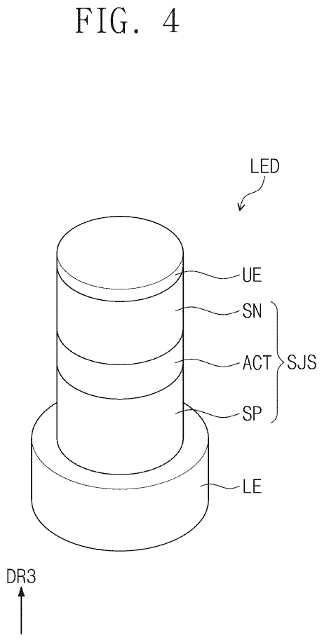

FIG. 4 illustrates in detail a perspective view of one light-emitting diode included in the display device according to one or more embodiments. A light-emitting diode LED will be described in detail with reference to FIG. 4. First to third light-emitting diodes LED1, LED2, and LED3 (see FIG. 6) to be described later may each have a stacked structure of the light-emitting diode LED described with reference to FIG. 4.

In FIG. 4, a lower conductive pattern LE and an upper conductive pattern UE are schematically illustrated as single layers, and a light-emitting structure SJS is illustrated in detail. FIG. 4 illustrates as an example the lower conductive pattern LE in a disk shape, and the light-emitting structure SJS and the upper conductive pattern UE in a cylinder shape, but the shapes of the lower conductive pattern LE, the light-emitting structure SJS, and the upper conductive pattern UE are not limited thereto.

The light-emitting structure SJS may be a layer substantially performing a light emitting function in the light-emitting diode LED. The light-emitting structure SJS may be referred to as a light-emitting layer. The light-emitting structure SJS may include an active layer ACT, a p-type semiconductor layer SP disposed on one side of the active layer ACT, and an n-type semiconductor layer SN disposed on the other side of the active layer ACT. In this embodiment, because the lower conductive pattern LE, which is an anode, is disposed under the active layer ACT, the p-type semiconductor layer SP is disposed under the active layer ACT. Unlike what is illustrated, when the upper conductive pattern UE disposed on the active layer ACT is an anode, the p-type semiconductor layer SP may be disposed on the active layer ACT.

The active layer ACT may be formed to have a single-quantum well or multi-quantum well structure. Light may be emitted by combination of electron-hole pairs according to electrical signals applied through the p-type semiconductor layer SP and the n-type semiconductor layer SN. The active layer ACT may emit light having a wavelength of about 400 nm to about 900 nm and may use a double hetero-structure.

In one or more embodiments of the present disclosure, the active layer ACT may have a structure in which semiconductor materials with large band gap energy and semiconductor materials with small band gap energy are alternately stacked and may include Group III to V semiconductor materials selected according to the wavelength range of the emitted light.

The p-type semiconductor layer SP may include at least one semiconductor material from among InAlGaN, GaN, AlGaN, InGaN, AlN, and/or InN, and may be doped with a first conductive-type dopant such as magnesium (Mg), zinc (Zn), calcium (Ca), and/or barium (Ba). For example, the p-type semiconductor layer SP may be a p-GaN doped with magnesium (Mg). However, materials constituting the p-type semiconductor layer SP are not limited thereto, and the p-type semiconductor layer SP may be composed of various materials other than the aforementioned materials.

The n-type semiconductor layer SN may include at least one semiconductor material from among InAlGaN, GaN, AlGaN, InGaN, AlN, and/or InN, and may be doped with a second conductive-type dopant such as silicon (Si), germanium (Ge), and/or tin (Sn). However, the materials constituting the n-type semiconductor layer SN are not limited thereto, and the n-type semiconductor layer SN may be composed of various materials other than the aforementioned materials.

In one or more embodiments, the light-emitting diode LED may further include a clad layer. The clad layer may be disposed on and/or under the active layer ACT. The clad layer may include an AlGaN layer or an InAlGaN layer. The light-emitting diode LED may further include a tensile strain barrier reducing layer (TSBR layer) disposed on and/or under the active layer ACT. The TSBR layer may be a strain relieve layer which is disposed between semiconductor layers with different lattice structures to serve as a buffer to reduce a lattice constant difference. The TSBR layer may be composed of the p-type semiconductor layer such as a p-GaInP, a p-AlInP, and/or a p-AlGaInP, but the present disclosure is not limited thereto.

In this embodiment, the lower conductive pattern LE may include at least one of a metal layer or a transparent conductive oxide layer. For example, the lower conductive pattern LE may include both the metal layer and the transparent conductive oxide layer. Alternatively, the lower conductive pattern LE may include either the metal layer or the transparent conductive oxide layer. The lower conductive pattern LE may further include a reflection layer. The lower conductive pattern LE may further include a functional layer disposed between the metal layer, the transparent conductive oxide layer, and the reflection layer. The functional layer may improve adhesive strength of each layer and may prevent diffusion of atoms between adjacent layers.

The metal layer may correspond to an adhesive layer that bonds the CMOS wafer and a semiconductor substrate during a manufacturing process of a display device. That is, the metal layer may be a layer formed by bonding the metal layer of the CMOS wafer and the metal layer of the semiconductor substrate.

The metal layer may be provided as a single layer or provided in plurality. The metal layer may include gold (Au), copper (Cu), silver (Ag), tin (Sn), titanium (Ti), zirconium (Zr), and/or tantalum (Ta), or an alloy of two metals thereof. When the metal layer is provided in plurality, the plurality of metal layers may have a structure in which sub-metal layers having different materials are alternately stacked.

The transparent conductive oxide layer may include indium tin oxide (ITO), indium zinc oxide (IZO), zinc oxide (ZnO), zinc tin oxide (ZTO), and/or indium gallium zinc oxide (IGZO). The transparent conductive oxide layer included in the lower conductive pattern LE may inject holes into the light-emitting structure SJS.

The reflection layer may reflect light generated from the light-emitting structure SJS back toward the light-emitting structure SJS. The reflection layer may include gold (Au), copper (Cu), silver (Ag), titanium (Ti), and/or aluminum (Al).

In this embodiment, the upper conductive pattern UE may include a transparent conductive oxide layer. The transparent conductive oxide layer may include indium tin oxide (ITO), indium zinc oxide (IZO), zinc oxide (ZnO), zinc tin oxide (ZTO), and/or indium gallium zinc oxide (IGZO). The transparent conductive oxide layer included in the upper conductive pattern UE may inject electrons into the light-emitting structure SJS.

The upper conductive pattern UE may further include an electrode metal layer disposed between the light-emitting structure SJS and the transparent conductive oxide layer composed of a transparent conductive oxide. The electrode metal layer may include a metal that has a lower work function than a second transparent conductive oxide layer. The electrode metal layer may improve the electron injection performance of the upper conductive pattern UE. The electrode metal layer may include aluminum (Al), titanium (Ti), indium (In), gold (Au), silver (Ag), nickel (Ni), and/or copper (Cu), an oxide thereof and/or an alloy thereof.

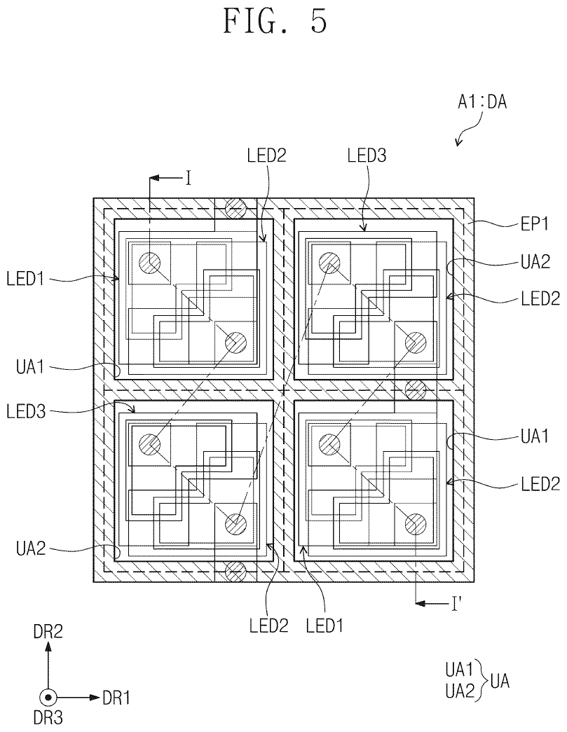

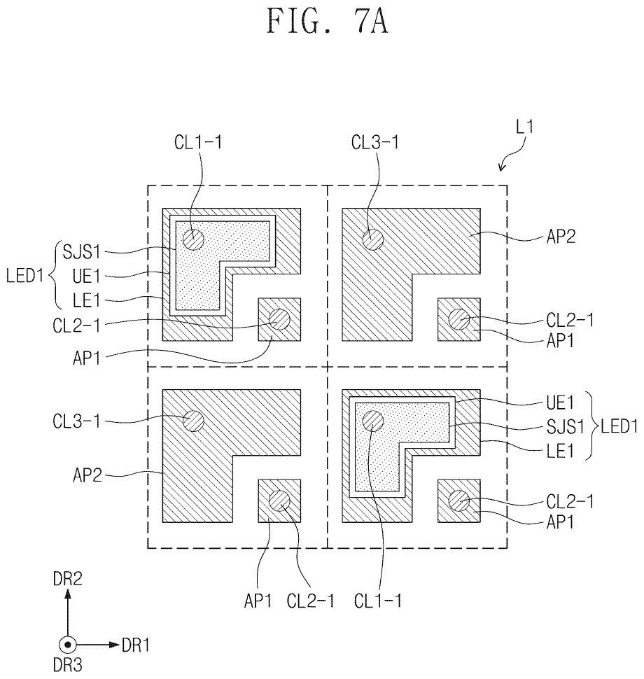

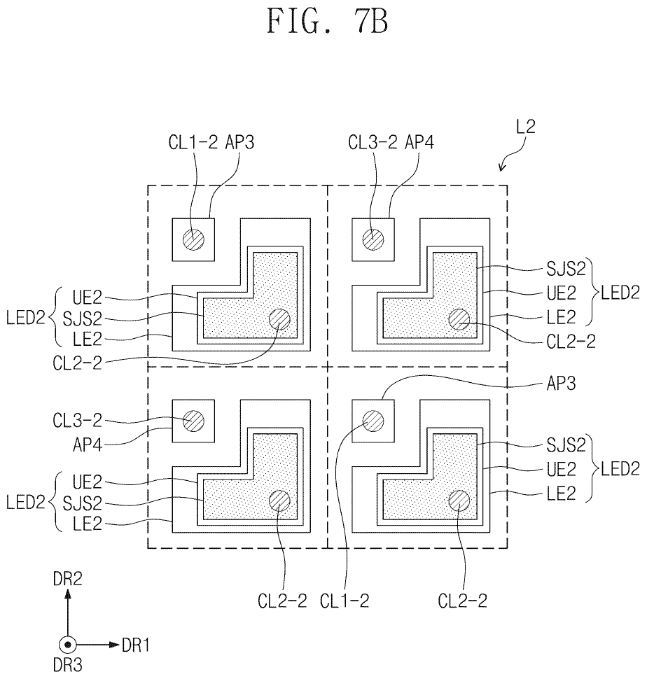

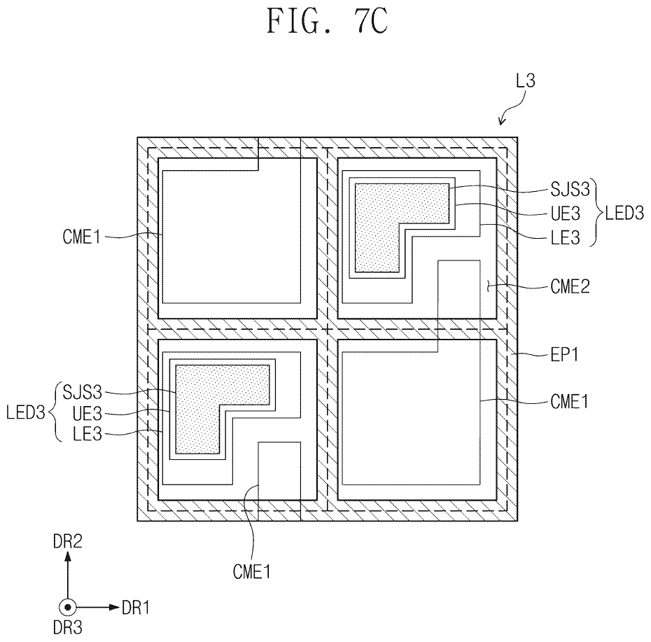

FIG. 5 is an enlarged plan view of a portion of the display device according to one or more embodiments of the present disclosure. FIG. 6 is an enlarged cross-sectional view of a portion of the display device according to one or more embodiments of the present disclosure. FIGS. 7A-7C are each a plan view of some components of the display device according to one or more embodiments of the present disclosure. FIG. 5 is an enlarged plan view of a portion A1 of the first region DA illustrated in FIG. 3A. FIG. 6 is a cross-sectional view taken along the line I-I′ illustrated in FIG. 5. FIGS. 7A-7C are each a plan view illustrating a planar arrangement of components, from among the components illustrated in FIG. 5, disposed corresponding to a first layer L1, a second layer L2, and a third layer L3.

Referring to FIGS. 5-6, the first region DA may include a plurality of unit regions UA and a boundary region BA between the unit regions UA. The boundary region BA may be a region with which the aforementioned electrode pattern EP (see FIG. 3B) overlaps. An electrode pattern, disposed corresponding to the first region DA, from among the electrode pattern EP (see FIG. 3B) may be referred to as a first electrode pattern EP1.

The plurality of light-emitting diodes LED1, LED2, and LED3 are disposed in each of the unit regions UA. The unit regions UA may include a first unit region UA1 in which the first light-emitting diode LED1 and the second light-emitting diode LED2 overlap, and a second unit region UA2 in which the second light-emitting diode LED2 and the third light-emitting diode LED3 overlap. The first light-emitting diode LED1, the second light-emitting diode LED2, and the third light-emitting diode LED3 may be respectively disposed on different layers, and two or more light-emitting diodes may be disposed in each of the unit regions UA. The first unit region UA1 and the second unit region UA2 may be disposed alternately along each of the first direction DR1 and the second direction DR2.

Referring to FIG. 5 to -7C together, the display device DD according to one or more embodiments may include the CMOS wafer 10, the light-emitting structure layer 20, and the lens layer 30.

The CMOS wafer 10 may include a silicon substrate 101. The silicon substrate 101 may include source/drain regions and a gate, which define a transistor. Shallow trench isolation (STI) regions for preventing a leakage current by isolating a transistor may be defined in the silicon substrate 101.

The CMOS wafer 10 may include a contact layer 102 disposed on the silicon substrate 101. In the first region DA, the contact layer 102 may include a plurality of contact electrodes CTE. The contact electrodes CTE may be connected to the source/drain regions of the silicon substrate 101. The contact electrodes CTE may be formed through a damascene process. The contact electrodes CTE may include at least one metal such as copper and/or tungsten. The contact electrodes CTE may include a tungsten structure, a titanium layer around (e.g., surrounding) a side surface and a bottom surface of the tungsten structure, and a titanium nitride layer around (e.g., surrounding) the titanium layer. The contact electrodes CTE may also include a copper structure, a tantalum layer around (e.g., surrounding) a side surface and a bottom surface of the copper structure, and a tantalum nitride layer around (e.g., surrounding) the tantalum layer.

The contact layer 102 may include a lower insulation layer INS-a disposed on the silicon substrate 101. The lower insulation layer INS-a may include an oxide layer such as a silicon oxide layer, a silicon nitride layer, a silicon oxynitride layer, and/or an aluminum oxide layer. A single-layered lower insulation layer INS-a is illustrated, but the lower insulation layer INS-a may be provided as a multilayer. Upper surfaces of the contact electrodes CTE may define a planar surface (or a flat surface) that is coplanar with an upper surface of the lower insulation layer INS-a.

The light-emitting structure layer 20 is disposed on the CMOS wafer 10 and includes a plurality of layers L1, L2, and L3. In the first region DA, the plurality of layers L1, L2, and L3 respectively include the plurality of light-emitting diodes LED1, LED2, and LED3.

A first layer L1 is disposed on the contact layer 102 of the CMOS wafer 10 and includes a plurality of first light-emitting diodes LED1. The plurality of first light-emitting diodes LED1 may be disposed corresponding to the first unit region UA1. The plurality of first light-emitting diodes LED1 may emit light of a first wavelength.

Each of the first light-emitting diodes LED1 may include a first light-emitting structure SJS1, a first lower conductive pattern LE1 disposed under the first light-emitting structure SJS1, and a first upper conductive pattern UE1 disposed on the first light-emitting structure SJS1.

The first lower conductive pattern LE1 may be directly disposed on the contact layer 102. The first lower conductive pattern LE1 may be in contact with each of the contact electrodes CTE of the contact layer 102. The first lower conductive pattern LE1 may include at least a metal. The first lower conductive pattern LE1 may include a metal layer. The metal layer of the first lower conductive pattern LE1 may connect the contact electrode CTE of the CMOS wafer 10 and the first lower conductive pattern LE1. The first lower conductive pattern LE1 may further include a transparent conductive oxide layer.

The first light-emitting structure SJS1 may be disposed on the first lower conductive pattern LE1 and include at least an active layer. The first light-emitting structure SJS1 may have a planar area smaller than or equal to that of the first lower conductive pattern LE1 disposed thereunder. The first light-emitting structure SJS1 may entirely overlap the first lower conductive pattern LE1.

The first upper conductive pattern UE1 may be disposed on the first light-emitting structure SJS1 and include a transparent conductive oxide. The first upper conductive pattern UE1 may have a planar area greater than or equal to that of the first light-emitting structure SJS1 disposed thereunder. The first light-emitting structure SJS1 may entirely overlap the first upper conductive pattern UE1. The first upper conductive pattern UE1 may have a planar area smaller than or equal to that of the first lower conductive pattern LE1.

The first layer L1 may further include first-layer additional conductive patterns AP1 and AP2. The first-layer additional conductive patterns AP1 and AP2 may be in contact with each of the contact electrodes CTE of the contact layer 102 and may be provided for electrical connection between the CMOS wafer 10 and second light-emitting diodes LED2 and third light-emitting diodes LED3 disposed thereabove. The first lower conductive pattern LE1 and the first-layer additional conductive patterns AP1 and AP2 may be disposed at the same layer. The first lower conductive pattern LE1 and the first-layer additional conductive patterns AP1 and AP2 may be formed through the same process and may include the same stacked structure and the same material. The first-layer additional conductive patterns AP1 and AP2 may include a first additional conductive pattern AP1 overlapping the second light-emitting diodes LED2 and a second additional conductive pattern AP2 overlapping the third light-emitting diodes LED3.

The first layer L1 may further include at least a first planarization layer INS1 disposed between the first light-emitting diodes LED1. The first planarization layer INS1 may overlap the unit regions UA and the boundary region BA, and may fill a region in which the first light-emitting diodes LED1 are not disposed. The first planarization layer INS1 may include an organic material. An upper surface of the first planarization layer INS1 may define a planar surface (or a flat surface) that is coplanar with an upper surface of the first upper conductive pattern UE1 of the first light-emitting diodes LED1.

A second layer L2 is disposed on the first layer L1 and includes the plurality of second light-emitting diodes LED2. The plurality of second light-emitting diodes LED2 may be disposed corresponding to each of the first unit region UA1 and the second unit region UA2. The plurality of second light-emitting diodes LED2 may emit light of a second wavelength different from the first wavelength.

The number of the second light-emitting diodes LED2 disposed per unit area may be twice the number of the first light-emitting diodes LED1 disposed per unit area. As illustrated in FIG. 5, when a region including two first unit regions UA1 and two second unit regions UA2 is defined as a unit area region, two first light-emitting diodes LED1 and four second light-emitting diodes LED2 may be disposed in the unit area region.

Each of the second light-emitting diodes LED2 may include a second light-emitting structure SJS2, a second lower conductive pattern LE2 disposed under the second light-emitting structure SJS2, and a second upper conductive pattern UE2 disposed on the second light-emitting structure SJS2.

The second lower conductive pattern LE2 may include a transparent conductive oxide. The second lower conductive pattern LE2 may not include a metal. Unlike the first lower conductive pattern LE1, the second lower conductive pattern LE2 may not include a metal and include only the transparent conductive oxide. The second lower conductive pattern LE2 may include only the transparent conductive oxide so as not to block the light generated from the first light-emitting diode LED1 disposed thereunder.

The second light-emitting structure SJS2 may be disposed on the second lower conductive pattern LE2 and include at least an active layer. The second light-emitting structure SJS2 may have a planar area smaller than or equal to that of the second lower conductive pattern LE2 disposed thereunder. The second light-emitting structure SJS2 may entirely overlap the second lower conductive pattern LE2.

The second upper conductive pattern UE2 may be disposed on the second light-emitting structure SJS2 and include a transparent conductive oxide. The second upper conductive pattern UE2 may have a planar area greater than or equal to that of the second light-emitting structure SJS2 disposed thereunder. The second light-emitting structure SJS2 may entirely overlap the second upper conductive pattern UE2. The second upper conductive pattern UE2 may have a planar area smaller than or equal to that of the second lower conductive pattern LE2.

A planar area of each of the plurality of second light-emitting diodes LED2 may be greater than or equal to a planar area of each of the plurality of first light-emitting diodes LED1. A planar area of each of the second light-emitting structures SJS2 included in the second light-emitting diodes LED2 may be greater than or equal to a planar area of each of the first light-emitting structures SJS1 included in the first light-emitting diodes LED1.

The second layer L2 may further include second-layer additional conductive patterns AP3 and AP4. The second-layer additional conductive patterns AP3 and AP4 may be provided for electrical connection between the first common electrode CME1 and the first light-emitting diodes LED1 disposed thereunder, and for electrical connection between the CMOS wafer 10 and the third light-emitting diodes LED3 disposed thereabove. The second-layer additional conductive patterns AP3 and AP4 and the second lower conductive pattern LE2 may be disposed at the same layer. The second-layer additional conductive patterns AP3 and AP4, and the second lower conductive pattern LE2 may be formed through the same process and include the same stacked structure and the same material. The second-layer additional conductive patterns AP3 and AP4 may include a third additional conductive pattern AP3 overlapping the first light-emitting diodes LED1 and a fourth additional conductive pattern AP4 overlapping the third light-emitting diodes LED3.

The second layer L2 may further include at least a second planarization layer INS2 disposed between the second light-emitting diodes LED2. The second planarization layer INS2 may overlap the unit regions UA and the boundary region BA, and may fill a region in which the second light-emitting diodes LED2 are not disposed. The second planarization layer INS2 may include an organic material. An upper surface of the second planarization layer INS2 may define a planar surface (or a flat surface) that is coplanar with an upper surface of the second upper conductive pattern UE2 of the second light-emitting diodes LED2.

A third layer L3 is disposed on the second layer L2 and includes the plurality of third light-emitting diodes LED3. The plurality of third light-emitting diodes LED3 may be disposed corresponding to the second unit region UA2. The plurality of third light-emitting diodes LED3 may emit light of a third wavelength different from the first wavelength and the second wavelength.

The number of the second light-emitting diodes LED2 disposed per unit area may be twice the number of the third light-emitting diodes LED3 disposed per unit area. As illustrated in FIG. 5, when a region including two first unit regions UA1 and two second unit regions UA2 is defined as a unit area region, two third light-emitting diodes LED3 and four second light-emitting diodes LED2 may be disposed in the unit area region.

Each of the third light-emitting diodes LED3 may include a third light-emitting structure SJS3, a third lower conductive pattern LE3 disposed under the third light-emitting structure SJS3, and a third upper conductive pattern UE3 disposed on the third light-emitting structure SJS3.

The third lower conductive pattern LE3 may include a transparent conductive oxide. The third lower conductive pattern LE3 may not include a metal. Unlike the first lower conductive pattern LE1, the third lower conductive pattern LE3 may not include a metal and include only the transparent conductive oxide. The third lower conductive pattern LE3 may include only the transparent conductive oxide so as not to block the light generated from the first light-emitting diode LED1 and the second light-emitting diode LED2 disposed thereunder.

The third light-emitting structure SJS3 may be disposed on the third lower conductive pattern LE3 and include at least an active layer. The third light-emitting structure SJS3 may have a planar area smaller than or equal to that of the third lower conductive pattern LE3 disposed thereunder. The third light-emitting structure SJS3 may entirely overlap the third lower conductive pattern LE3.

The third upper conductive pattern UE3 may be disposed on the third light-emitting structure SJS3 and include a transparent conductive oxide. The third upper conductive pattern UE3 may have a planar area greater than or equal to that of the third light-emitting structure SJS3 disposed thereunder. The third light-emitting structure SJS3 may entirely overlap the third upper conductive pattern UE3. The third upper conductive pattern UE3 may have a planar area smaller than or equal to that of the third lower conductive pattern LE3.

A planar area of each of the plurality of third light-emitting diodes LED3 may be greater than or equal to a planar area of each of the plurality of second light-emitting diodes LED2. A planar area of each of the third light-emitting structures SJS3 included in the third light-emitting diodes LED3 may be greater than or equal to a planar area of each of the second light-emitting structures SJS2 included in the second light-emitting diodes LED2.

The third layer L3 may further include at least a third planarization layer INS3 disposed between the third light-emitting diodes LED3. The third planarization layer INS3 may overlap the unit regions UA and the boundary region BA, and may fill a region in which the third light-emitting diodes LED3 are not disposed. The third planarization layer INS3 may include an organic material. An upper surface of the third planarization layer INS3 may define a planar surface (or a flat surface) that is coplanar with an upper surface of the third upper conductive pattern UE3 of the third light-emitting diodes LED3.

The light-emitting structure layer 20 further includes a first common electrode CME1 and a second common electrode CME2. The first common electrode CME1 is connected to at least some light-emitting diodes from among the first light-emitting diodes LED1, the second light-emitting diodes LED2, and the third light-emitting diodes LED3. The second common electrode CME2 is connected to at least some light-emitting diodes from among the rest of the first light-emitting diodes LED1, the second light-emitting diodes LED2, and the third light-emitting diodes LED3, which are not connected to the first common electrode CME1. In the display device DD according to the embodiment illustrated in FIGS. 5-7C, the first common electrode CME1 may be connected to the first light-emitting diodes LED1 and the second light-emitting diodes LED2, and the second common electrode CME2 may be connected to the third light-emitting diodes LED3.

The first common electrode CME1 and the third lower conductive pattern LE3 may be disposed at the same layer. The first common electrode CME1 and the third lower conductive pattern LE3 may be formed through the same process and include the same stacked structure and the same material. The first common electrode CME1 may include a transparent conductive oxide. The second common electrode CME2 may be disposed on the third layer L3. The second common electrode CME2 may include a transparent conductive oxide.

The light-emitting structure layer 20 further includes a first electrode pattern EP1 and the first electrode pattern EP1 has a mesh structure on a plane (e.g., in a plan view (e.g., see FIG. 3B)). The first electrode pattern EP1 may be disposed corresponding to the boundary region BA. The first electrode pattern EP1 may not overlap, on a plane (e.g., in a plan view), each of the first light-emitting diodes LED1, the second light-emitting diodes LED2, and the third light-emitting diodes LED3.

The first electrode pattern EP1 is disposed in the third layer L3 and electrically connects the first common electrode CME1 and the second common electrode CME2. The first electrode pattern EP1 and the third light-emitting structure SJS3 of the third light-emitting diode LED3 may be disposed at the same layer. The first electrode pattern EP1 may be in contact with an upper surface of the first common electrode CME1 and a lower surface of the second common electrode CME2 and thus electrically connect the first common electrode CME1 and the second common electrode CME2.

The light-emitting structure layer 20 may further include optical layers DBR1 and DBR2. The optical layers DBR1 and DBR2 may be disposed between the first layer L1 and the second layer L2 and/or between the second layer L2 and the third layer L3. For example, the optical layers DBR1 and DBR2 may include a first optical layer DBR1 disposed between the first layer L1 and the second layer L2, and a second optical layer DBR2 disposed between the second layer L2 and the third layer L3. In one or more embodiments, one of the first optical layer DBR1 or the second optical layer DBR2 may be omitted.

The first optical layer DBR1 and the second optical layer DBR2 may each include a plurality of sub layers SL1 and SL2. The first optical layer DBR1 and the second optical layer DBR2 may each include a first sub layer SL1 having a first refractive index, and a second sub layer SL2 having a second refractive index different from the first refractive index. The first sub layer SL1 and the second sub layer SL2 may be each provided in plurality, and may be disposed alternately. The first optical layer DBR1 and the second optical layer DBR2 may each have a structure in which the first sub layer SL1 and the second sub layer SL2 having different refractive indexes are disposed alternately, and may thus reflect light of a specific wavelength and transmit light of other wavelengths. For example, the first optical layer DBR1 may transmit light of a wavelength emitted from the first light-emitting diode LED1 and reflect light of a wavelength emitted from the second light-emitting diode LED2 and the third light-emitting diode LED3. The second optical layer DBR2 may transmit light of a wavelength emitted from the first light-emitting diode LED1 and the second light-emitting diode LED2 and reflect light of a wavelength of emitted from the third light-emitting diode LED3.

The light-emitting structure layer 20 may further include connection lines CL1, CL2, and CL3. Each of the connection lines CL1, CL2, and CL3 may be provided for electrical connection between the light-emitting diodes LED1, LED2, and LED3 and the first common electrode CME1 and the CMOS wafer 10. Each of the connection lines CL1, CL2, and CL3 may be formed through a damascene process. The connection lines CL1, CL2, and CL3 may each include at least one metal such as copper and/or tungsten.

First connection lines CL1 may be disposed on the respective first light-emitting diodes LED1. The first connection lines CL1 may overlap the first light-emitting diodes LED1 on a plane (e.g., in a plan view), and may electrically connect the first common electrode CME1 and the first light-emitting diodes LED1. The first connection line CL1 may include a (1-1)-th connection line CL1-1 disposed between the first upper conductive pattern UE1 of the first light-emitting diode LED1 and the third additional conductive pattern AP3, and a (1-2)-th connection line CL1-2 disposed between the third additional conductive pattern AP3 and the first common electrode CME1. The first lower conductive pattern LE1 of the first light-emitting diode LED1 may be in direct contact with the contact electrode CTE and thus may be electrically connected to the CMOS wafer 10. The first upper conductive pattern UE1 of the first light-emitting diode LED1 may be electrically connected to the first common electrode CME1 via the (1-1)-th connection line CL1-1, the third additional conductive pattern AP3, and the (1-2)-th connection line CL1-2, which are sequentially disposed therebetween.

Second connection lines CL2 may be disposed on and under the respective second light-emitting diodes LED2. The second connection lines CL2 may overlap the second light-emitting diodes LED2 on a plane (e.g., in a plan view), and may electrically connect the first common electrode CME1 and the CMOS wafer 10 to the second light-emitting diodes LED2. The second connection line CL2 may include a (2-1)-th connection line CL2-1 disposed between the second lower conductive pattern LE2 of the second light-emitting diode LED2 and the first additional conductive pattern AP1, and a (2-2)-th connection line CL2-2 disposed between the second upper conductive pattern UE2 of the second light-emitting diode LED2 and the first common electrode CME1. The second lower conductive pattern LE2 of the second light-emitting diode LED2 may be electrically connected to the CMOS wafer 10 via the (2-1)-th connection line CL2-1 and the first additional conductive pattern AP1 which are sequentially disposed therebetween. The second upper conductive pattern UE2 of the second light-emitting diode LED2 may be electrically connected to the first common electrode CME1 by the (2-2)-th connection line CL2-2 disposed therebetween.

Third connection lines CL3 may be disposed under the respective third light-emitting diodes LED3. The third connection lines CL3 may overlap the third light-emitting diodes LED3 on a plane (e.g., in a plan view), and may electrically connect the CMOS wafer and the third light-emitting diodes LED3. The third connection line CL3 may include a (3-2)-th connection line CL3-2 disposed between the third lower conductive pattern LE3 of the third light-emitting diode LED3 and the fourth additional conductive pattern AP4, and a (3-1)-th connection line CL3-1 disposed between the fourth additional conductive pattern AP4 and the second additional conductive pattern AP2. The third upper conductive pattern UE3 of the third light-emitting diode LED3 may be in direct contact with the second common electrode CME2 and thus may be electrically connected to the second common electrode CME2. The third lower conductive pattern LE3 of the third light-emitting diodes LED3 may be electrically connected to the CMOS wafer 10 via the second additional conductive pattern AP2, the (3-1)-th connection line CL3-1, the fourth additional conductive pattern AP4, and the (3-2)-th connection line CL3-2, which are disposed sequentially therebetween.

The first light-emitting diodes LED1, the second light-emitting diodes LED2, and the third light-emitting diodes LED3 may not at least partially overlap each other on a plane (e.g., in a plan view). A portion of each of the first light-emitting diodes LED1 may overlap the second light-emitting diodes LED2 on a plane (e.g., in a plan view) and the rest may not overlap the second light-emitting diodes LED2. Each of the first light-emitting diodes LED1 may not overlap the third light-emitting diodes LED3 on a plane (e.g., in a plan view). A portion of each of the second light-emitting diodes LED2 may overlap each of the first light-emitting diodes LED1 or the third light-emitting diodes LED3 on a plane (e.g., in a plan view) and the rest may not overlap each of the first light-emitting diodes LED1 or the third light-emitting diodes LED3. A portion of each of the third light-emitting diodes LED3 may overlap the second light-emitting diodes LED2 on a plane (e.g., in a plan view) and the rest may not overlap the second light-emitting diodes LED2. In a region where being connected to the connection lines CL1, CL2, and CL3, the first light-emitting diodes LED1, the second light-emitting diodes LED2, and the third light-emitting diodes LED3 may each not overlap other light-emitting diodes.

In one or more embodiments, the first layer L1, the second layer L2, and the third layer L3 may each include a side surface insulation layer and a side surface reflection layer that are disposed on side surfaces of each of the plurality of light-emitting diodes LED1, LED2, and LED3. The side surface reflection layer may improve light efficiency by reflecting light generated from the light-emitting diodes LED1, LED2, and LED3 and directing the light to propagate upwards. The side surface insulation layer may protect the light-emitting diodes LED1, LED2, and LED3 and prevent contact between the side surface reflection layer and the light-emitting diodes LED1, LED2, and LED3. The side surface insulation layer may include a silicon oxide layer, a silicon nitride layer, a silicon oxynitride layer, an aluminum oxide layer, a zirconium oxide layer, hafnium oxide layer, and/or a titanium oxide layer. The side surface reflection layer may include gold (Au), copper (Cu), silver (Ag), titanium (Ti), and/or aluminum (Al).

The lens layer 30 may be disposed on the light-emitting structure layer 20 and include a plurality of lenses LS. The lens layer 30 may further include a passivation layer BS-L which provides a base surface on which the lens LS is disposed. The passivation layer BS-L may be disposed on the second common electrode CME2 and protect the second common electrode CME2. The passivation layer BS-L may include an organic material or an inorganic material.

The lens LS may be disposed to overlap at least the light-emitting diodes LED1, LED2, and LED3. As illustrated in FIG. 6, the lens LS may be disposed corresponding to each of the first unit region UA1 and the second unit region UA2. One lens LS may be provided to each first unit region UA1 and one lens LS may be provided to each second unit region UA2. The lens LS provided to the first unit region UA1 may be disposed corresponding to one first light-emitting diode LED1 and one second light-emitting diode LED2, and the lens LS provided to the second unit region UA2 may be disposed corresponding to one second light-emitting diode LED2 and one third light-emitting diode LED3. Each of the lenses LS may have a circular shape on a plane (e.g., in a plan view (e.g., each of the lenses LS may have a semi-circular shape in a cross section)) and the diameter of each of the lenses LS may be smaller than about one micrometer.

The display device DD according to one or more embodiments may have a structure in which the light-emitting diodes LED1, LED2, and LED3 are provided as multilayers, and thereby have high resolution. The high resolution of the display device DD may cause a voltage drop to occur greatly in the common electrode, but the display device DD according to one or more embodiments includes the first common electrode CME1 and the second common electrode CME2 provided as multilayers and has a structure in which the first common electrode CME1 and the second common electrode CME2 are electrically connected through the electrode pattern EP1, thereby reducing the voltage drop which occurs in the common electrode. Accordingly, the resolution of display device DD may be improved and defects may be reduced.

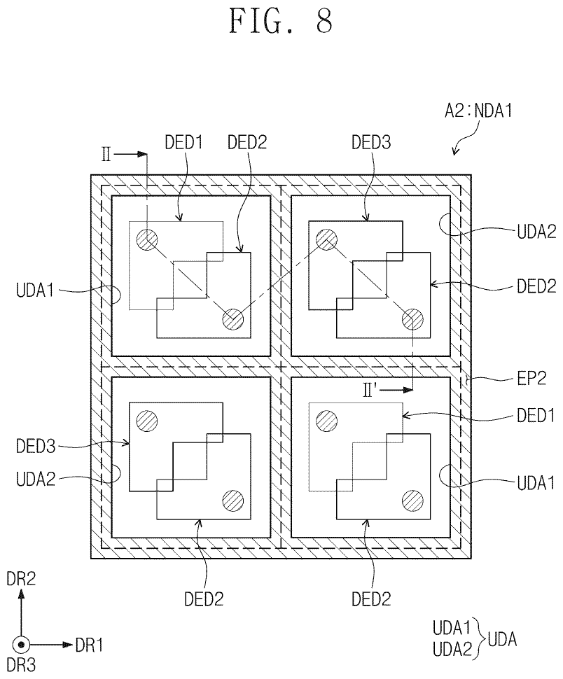

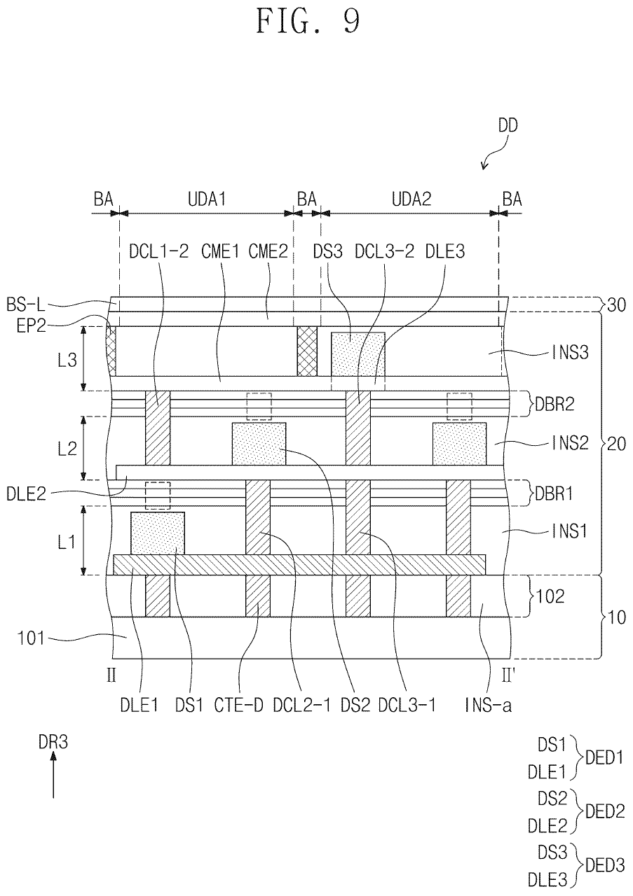

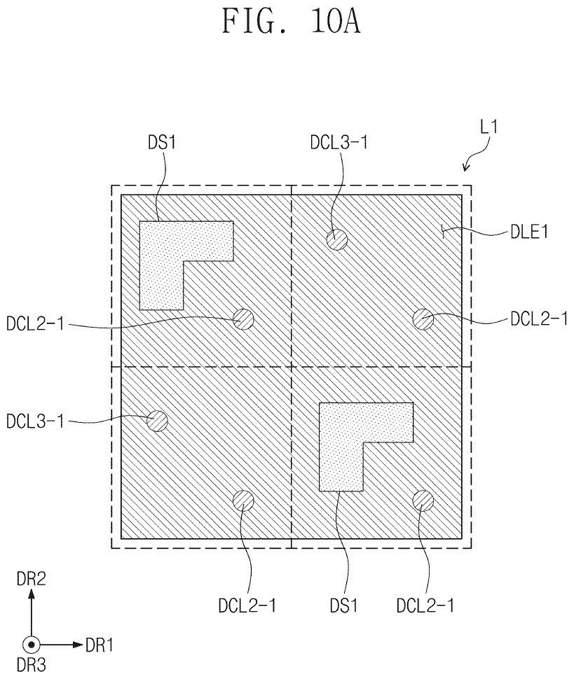

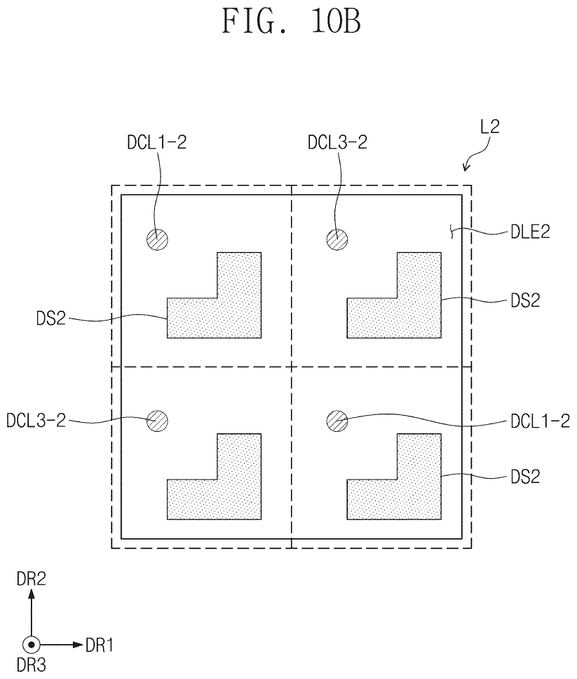

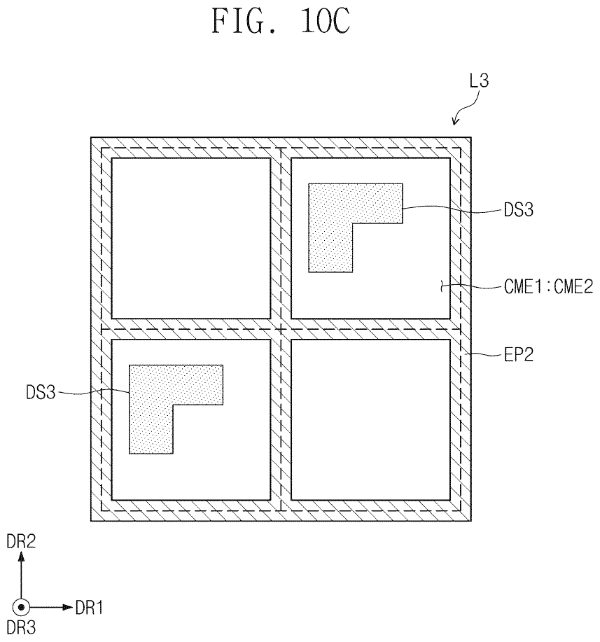

FIG. 8 is an enlarged plan view of a portion of the display device according to one or more embodiments of the present disclosure. FIG. 9 is an enlarged cross-sectional view of a portion of the display device according to one or more embodiments of the present disclosure. FIGS. 10A-10C are each a plan view of some components of the display device according to one or more embodiments of the present disclosure. FIG. 8 is an enlarged plan view of a portion A2 of the second region NDA1 illustrated in FIG. 3A. FIG. 9 is a cross-sectional view taken along the line II-II′ illustrated in FIG. 8. FIGS. 10A-10C are each a plan view illustrating a planar arrangement of components, from among the components illustrated in FIG. 8, disposed corresponding to the first layer L1, the second layer L2, and the third layer L3.

Referring to FIG. 8, the second region NDA1 may include a plurality of dummy unit regions UDA and a boundary region BA between the dummy unit regions UDA. The boundary region BA may be a region with which the aforementioned electrode pattern EP (see FIG. 3B) overlaps. An electrode pattern, disposed corresponding to the second region NDA1, of the electrode pattern EP (see FIG. 3B) may be referred to as a second electrode pattern EP2.

A plurality of dummy light-emitting diodes DED1, DED2, and DED3 are disposed in each of the dummy unit regions UDA. The dummy unit regions UDA may include a first dummy unit region UDA1 in which a first dummy light-emitting diode DED1 and a second dummy light-emitting diode DED2 overlap, and a second dummy unit region UDA2 in which the second dummy light-emitting diode DED2 and a third dummy light-emitting diode DED3 overlap. The first dummy light-emitting diode DED1, the second dummy light-emitting diode DED2, and the third dummy light-emitting diode DED3 may be respectively disposed on different layers, and two or more dummy light-emitting diodes may be disposed in each dummy unit region UDA. The first dummy unit region UDA1 and the second dummy unit region UDA2 may be disposed alternately along each of the first direction DR1 and the second direction DR2.

Referring to FIGS. 8-10C together, the display device DD according to one or more embodiments may include the CMOS wafer 10 and the light-emitting structure layer 20.

The CMOS wafer 10 may include the silicon substrate 101 and the contact layer 102 disposed on the silicon substrate 101. In the second region NDA1, the contact layer 102 may include a plurality of dummy contact electrodes CTE-D. The dummy contact electrodes CTE-D may be connected to the source/drain regions of the silicon substrate 101. The dummy contact electrodes CTE-D may be formed through a damascene process. The dummy contact electrodes CTE-D may include at least one metal such as copper and/or tungsten. The dummy contact electrodes CTE-D and the aforementioned contact electrodes CTE (see FIG. 6) may be formed through the same process and may have the same material and structure.

The contact layer 102 may include a lower insulation layer INS-a disposed on the silicon substrate 101. Upper surfaces of the dummy contact electrodes CTE-D may define a planar surface (or a flat surface) that is coplanar with an upper surface of the lower insulation layer INS-a.

The light-emitting structure layer 20 is disposed on the CMOS wafer 10 and includes the plurality of layers L1, L2, and L3. In the second region NDA1, the plurality of layers L1, L2, and L3 respectively include the plurality of dummy light-emitting diodes DED1, DED2, and DED3.

The first layer L1 is disposed on the contact layer 102 of the CMOS wafer 10 and includes the plurality of first dummy light-emitting diodes DED1. The plurality of first dummy light-emitting diodes DED1 may be disposed corresponding to the first dummy unit region UDA1.

Each of the first dummy light-emitting diodes DED1 may include a first dummy structure DS1 and a first lower dummy pattern DLE1 disposed under the first dummy structure DS1.

The first lower dummy pattern DLE1 may be directly disposed on the contact layer 102. The first lower dummy pattern DLE1 may be in contact with each of the dummy contact electrodes CTE-D of the contact layer 102. The first lower dummy pattern DLE1 and the aforementioned first lower conductive pattern LE1 (see FIG. 6) may be formed through the same process and may have the same material and stacked structure. The first lower dummy pattern DLE1 and the first lower conductive pattern LE1 (see FIG. 6) may be disposed at the same layer.

The first dummy structure DS1 may be disposed on the first lower dummy pattern DLE1 and include at least an active layer. The first dummy structure DS1 may have a planar area smaller than or equal to that of the first lower dummy pattern DLE1 disposed thereunder. The first dummy structure DS1 may entirely overlap the first lower dummy pattern DLE1. The first dummy structure DS1 and the aforementioned first light-emitting structure SJS1 (see FIG. 6) may be formed through the same process and may have the same material and stacked structure. The first dummy structure DS1 and the first light-emitting structure SJS1 (see FIG. 6) may be disposed at the same layer.

Unlike the first light-emitting diode LED1 (see FIG. 6) disposed in the first region DA (see FIG. 5), the first dummy light-emitting diode DED1 may have a structure in which an upper conductive pattern is omitted. Because the upper conductive pattern is omitted, the first dummy light-emitting diode DED1 is not electrically connected to the first common electrode CME1 and is thus unable to operate (or emit light).

The first layer L1 may further include at least the first planarization layer INS1 disposed between the first dummy light-emitting diodes DED1. The first planarization layer INS1 may overlap the dummy unit regions UDA and the boundary region BA, and may fill a region in which the first dummy light-emitting diodes DED1 are not disposed. The first planarization layer INS1 may include an organic material.

The second layer L2 is disposed on the first layer L1 and includes the plurality of second dummy light-emitting diodes DED2. The plurality of second dummy light-emitting diodes DED2 may be disposed corresponding to each of the first dummy unit region UDA1 and the second dummy unit region UDA2. The number of the second dummy light-emitting diodes DED2 disposed per unit area may be twice the number of the first dummy light-emitting diodes DED1 disposed per unit area. As illustrated in FIG. 8, when a region including two first dummy unit regions UDA1 and two second dummy unit regions UDA2 is defined as a unit area region, two first dummy light-emitting diodes DED1 and four second dummy light-emitting diodes DED2 may be disposed in the unit area region.

Each of the second dummy light-emitting diodes DED2 may include a second dummy structure DS2 and a second lower dummy pattern DLE2 disposed under the second dummy structure DS2.

The second lower dummy pattern DLE2 and the aforementioned second lower conductive pattern LE2 (see FIG. 6) may be formed through the same process and may have the same material and stacked structure. The second lower dummy pattern DLE2 and the second lower conductive pattern LE2 (see FIG. 6) may be disposed at the same layer. The second lower dummy pattern DLE2 may not include a metal and include only a transparent conductive oxide.

The second dummy structure DS2 may be disposed on the second lower dummy pattern DLE2 and include at least an active layer. The second dummy structure DS2 may have a planar area smaller than or equal to that of the second lower dummy pattern DLE2 disposed thereunder. The second dummy structure DS2 may entirely overlap the second lower dummy pattern DLE2. The second dummy structure DS2 and the aforementioned second light-emitting structure SJS2 (see FIG. 6) may be formed through the same process and may have the same material and stacked structure. The second dummy structure DS2 and the second light-emitting structure SJS2 (see FIG. 6) may be disposed at the same layer.

Unlike the second light-emitting diode LED2 (see FIG. 6) disposed in the first region DA (see FIG. 5), the second dummy light-emitting diode DED2 may have a structure in which an upper conductive pattern is omitted. Because the upper conductive pattern is omitted, the second dummy light-emitting diode DED2 is not electrically connected to the first common electrode CME1 and is thus unable to operate (or emit light).

The second layer L2 may further include at least the second planarization layer INS2 disposed between the second dummy light-emitting diodes DED2. The second planarization layer INS2 may overlap the dummy unit regions UDA and the boundary region BA, and may fill a region in which the second dummy light-emitting diodes DED2 are not disposed. The second planarization layer INS2 may include an organic material.

The third layer L3 is disposed on the second layer L2 and includes the plurality of third dummy light-emitting diodes DED3. The plurality of third dummy light-emitting diodes DED3 may be disposed corresponding to the second dummy unit region UDA2. The number of the second dummy light-emitting diodes DED2 disposed per unit area may be twice the number of the third dummy light-emitting diodes DED3 disposed per unit area. As illustrated in FIG. 8, when a region including two first dummy unit regions UDA1 and two second dummy unit regions UDA2 is defined as a unit area region, two third dummy light-emitting diodes DED3 and four second dummy light-emitting diodes DED2 may be disposed in the unit area region.

Each of the third dummy light-emitting diodes DED3 may include a third dummy structure DS3 and a third lower dummy pattern DLE3 disposed under the third dummy structure DS3.

The third lower dummy pattern DLE3 and the aforementioned third lower conductive pattern LE3 (see FIG. 6) may be formed through the same process and may have the same material and stacked structure. The third lower dummy pattern DLE3 and the third lower conductive pattern LE3 (see FIG. 6) may be disposed at the same layer. The third lower dummy pattern DLE3 may not include a metal and include only a transparent conductive oxide.

The third dummy structure DS3 may be disposed on the third lower dummy pattern DLE3 and include at least an active layer. The third dummy structure DS3 may have a planar area smaller than or equal to that of the third lower dummy pattern DLE3 disposed thereunder. The third dummy structure DS3 may entirely overlap the third lower dummy pattern DLE3. The third dummy structure DS3 and the aforementioned third light-emitting structure SJS3 (see FIG. 6) may be formed through the same process and may have the same material and stacked structure. The third dummy structure DS3 and the third light-emitting structure SJS3 (see FIG. 6) may be disposed at the same layer.

Unlike the third light-emitting diode LED3 (see FIG. 6) disposed in the first region DA (see FIG. 5), the third dummy light-emitting diode DED3 may have a structure in which an upper conductive pattern is omitted. Because the upper conductive pattern is omitted, the third dummy light-emitting diode DED3 is not electrically connected to the second common electrode CME2 and is thus unable to operate (or emit light).

The third layer L3 may further include at least the third planarization layer INS3 disposed between the third dummy light-emitting diodes DED3. The third planarization layer INS3 may overlap the dummy unit regions UDA and the boundary region BA, and may fill a region in which the third dummy light-emitting diodes DED3 are not disposed. The third planarization layer INS3 may include an organic material.

The light-emitting structure layer 20 may further include the first common electrode CME1 and the second common electrode CME2. In the second region NDA1, the first common electrode CME1 and the second common electrode CME2 are both not connected to the first dummy light-emitting diodes DED1, the second dummy light-emitting diodes DED2, or the third dummy light-emitting diodes DED3.

The first common electrode CME1 and the third lower dummy pattern DLE3 may be disposed at the same layer. The first common electrode CME1 and the third lower dummy pattern DLE3 may be formed through the same process and may have the same stacked structure and the same material. The first common electrode CME1 may include a transparent conductive oxide. The second common electrode CME2 may be disposed on the third layer L3. The second common electrode CME2 may include a transparent conductive oxide.

The light-emitting structure layer 20 further includes a second electrode pattern EP2, and the second electrode pattern EP2 has a mesh structure on a plane (e.g., in a plan view). The second electrode pattern EP2 may be disposed corresponding to the boundary region BA. The second electrode pattern EP2 may not overlap, on a plane (e.g., in a plan view), each of the first dummy light-emitting diodes DED1, the second dummy light-emitting diodes DED2, and the third dummy light-emitting diodes DED3. The second electrode pattern EP2 and the aforementioned first electrode pattern EP1 (see FIG. 6) may be formed through the same process and may have the same material. The second electrode pattern EP2 and the first electrode pattern EP1 (see FIG. 6) may have an integrated shape.

The second electrode pattern EP2 is disposed in the third layer L3 and electrically connects the first common electrode CME1 and the second common electrode CME2. The second electrode pattern EP2 and the third dummy structure DS3 of the third dummy light-emitting diode DED3 may be disposed at the same layer. The second electrode pattern EP2 may be in contact with the upper surface of the first common electrode CME1 and the lower surface of the second common electrode CME2 and thus electrically connect the first common electrode CME1 and the second common electrode CME2.

The light-emitting structure layer 20 may further include the optical layers DBR1 and DBR2. The optical layers DBR1 and DBR2 may be disposed between the first layer L1 and the second layer L2 and/or between the second layer L2 and the third layer L3. The optical layers DBR1 and DBR2 may include, for example, the first optical layer DBR1 disposed between the first layer L1 and the second layer L2, and the second optical layer DBR2 disposed between the second layer L2 and the third layer L3. In one or more embodiments, at least one of the first optical layer DBR1 or the second optical layer DBR2 may be omitted.

The light-emitting structure layer 20 may further include dummy lines DCL. Each of the dummy lines DCL may be provided for electrical connection between the CMOS wafer 10 and the first common electrode CME1. Each of the dummy lines DCL may be formed through a damascene process. The dummy lines DCL may each include at least one metal such as copper and/or tungsten. The dummy lines DCL may include a (1-2)-th dummy line DCL1-2 disposed on the first dummy light-emitting diode DED1, a (2-1) dummy line DCL2-1 disposed under the second dummy light-emitting diode DED2, and a (3-1)-th dummy line DCL3-1 and a (3-2)-th dummy line DCL3-2 that are disposed under the third dummy light-emitting diode DED3.

The first dummy light-emitting diodes DED1, the second dummy light-emitting diodes DED2, and the third dummy light-emitting diodes DED3 may not at least partially overlap each other on a plane (e.g., in a plan view). A portion of each of the first dummy light-emitting diodes DED1 may overlap the second dummy light-emitting diodes DED2 on a plane (e.g., in a plan view) and the rest may not overlap the second dummy light-emitting diodes DED2. Each of the first dummy light-emitting diodes DED1 may not overlap the third dummy light-emitting diodes DED3 on a plane (e.g., in a plan view). A portion of each of the second dummy light-emitting diodes DED2 may overlap each of the first dummy light-emitting diodes DED1 or the third dummy light-emitting diodes DED3 on a plane (e.g., in a plan view) and the rest may not overlap each of the first dummy light-emitting diodes DED1 or the third dummy light-emitting diodes DED3. A portion of each of the third dummy light-emitting diodes DED3 may overlap the second dummy light-emitting diodes DED2 on a plane (e.g., in a plan view) and the rest may not overlap the second dummy light-emitting diodes DED2. In a region where being connected to the dummy line DCL, the first dummy light-emitting diodes DED1, the second dummy light-emitting diodes DED2, and the third dummy light-emitting diodes DED3 may each not overlap other dummy light-emitting diodes.

In one or more embodiments, the first layer L1, the second layer L2, and the third layer L3 may each include a side surface insulation layer and a side surface reflection layer that are disposed on side surfaces of each of the plurality of dummy light-emitting diodes DED1, DED2, and DED3.

Unlike the first region DA, the lens disposed on the light-emitting structure layer 20 may be omitted in the second region NDA1. Because the dummy light-emitting diodes DED1, DED2, and DED3 disposed in the second region NDA1 do not substantially generate light, the lenses disposed on the light-emitting structure layer may be omitted. However, the present disclosure is not limited thereto, and lenses may also be disposed on the light-emitting structure layer 20 in the second region NDA1 to correspond to the dummy unit regions UDA.

FIGS. 8-10C each illustrate a planar arrangement and cross-sectional stacked structure in the portion A2 of the second region NDA1 illustrated in FIG. 3A, but the same planar arrangement and cross-sectional stacked structure may also be applied to a portion A3 of the pad region PDA illustrated in FIG. 3A. Portions of the common electrodes CME1 and CME2 disposed corresponding to the pad region PDA may correspond to the voltage transfer electrode VTE illustrated in FIG. 3A.

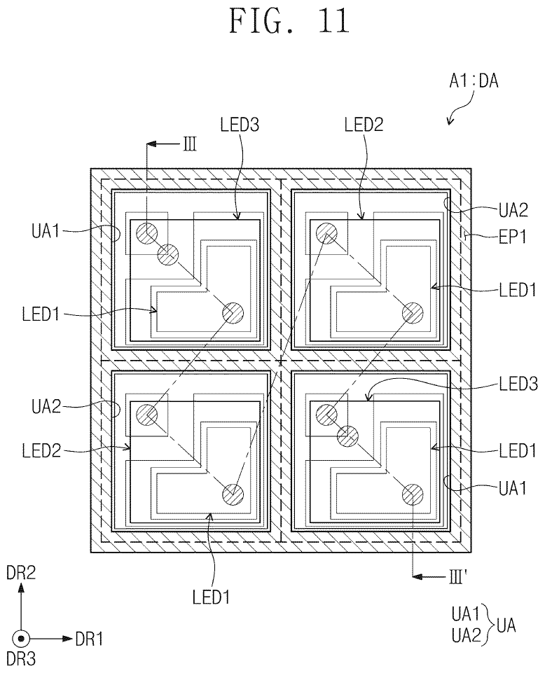

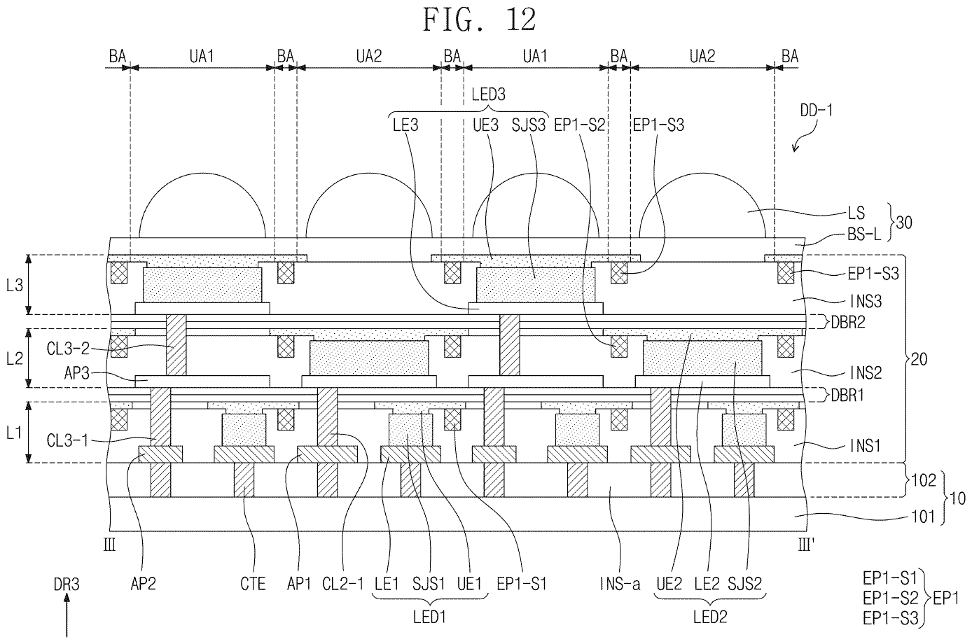

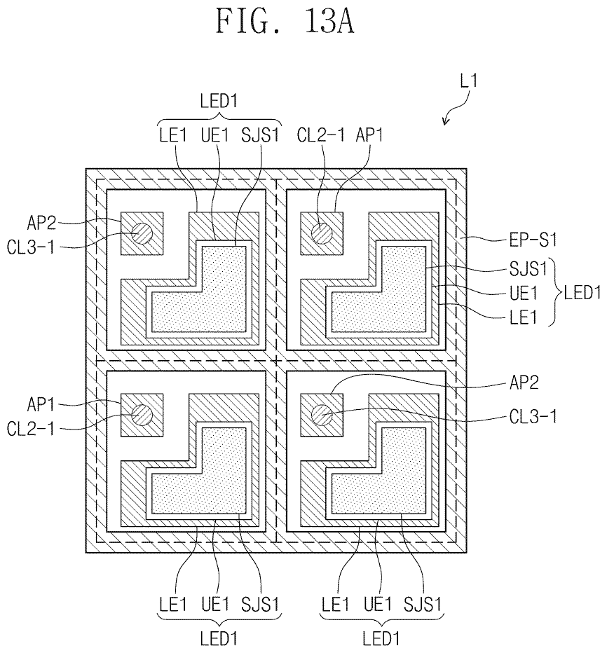

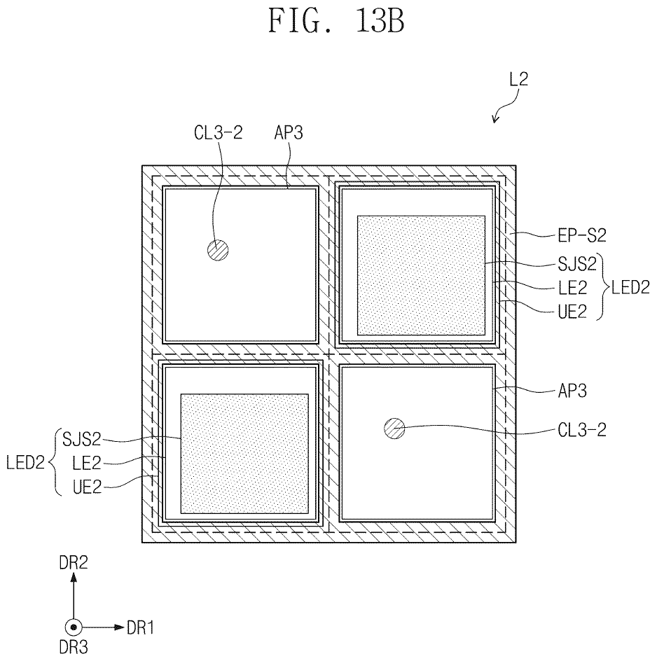

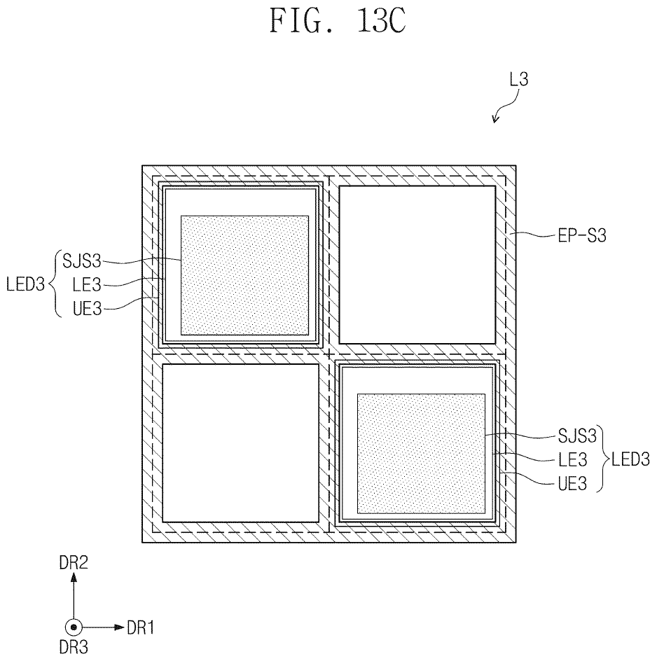

FIG. 11 is an enlarged plan view of a portion of a display device according to one or more embodiments of the present disclosure. FIG. 12 is an enlarged cross-sectional view of a portion of the display device according to one or more embodiments of the present disclosure. FIGS. 13A-13C are each a plan view of some components of the display device according to one or more embodiments of the present disclosure. FIG. 11 is an enlarged plan view of a portion A1 of a first region DA illustrated in FIG. 3A. FIG. 12 is a cross-sectional view taken along the line III-III′ illustrated in FIG. 11. FIGS. 13A-13C are each a plan view illustrating a planar arrangement of components, from among the components illustrated in FIG. 11, disposed corresponding to a first layer L1, a second layer L2, and a third layer L3. FIGS. 11-13C each illustrate a plan view and a cross-sectional view which corresponds to a portion of a first region DA in a display device DD-1 according to another embodiment that is different from the display device DD according to the embodiment illustrated in FIGS. 5-7C.

Referring to FIG. 11, the first region DA may include a plurality of unit regions UA and a boundary region BA between the unit regions UA. The boundary region BA may be a region with which the aforementioned electrode pattern EP (see FIG. 3B) overlaps. An electrode pattern, disposed corresponding to the first region DA, from among the electrode pattern EP (see FIG. 3B) may be referred to as a first electrode pattern EP1.

A plurality of light-emitting diodes LED1, LED2, and LED3 are disposed in each of the unit regions UA. The unit regions UA may include a first unit region UA1 in which a first light-emitting diode LED1 and a third light-emitting diode LED3 overlap, and a second unit region UA2 in which the first light-emitting diode LED1 and a second light-emitting diode LED2 overlap. The first light-emitting diode LED1, the second light-emitting diode LED2, and the third light-emitting diode LED3 may be respectively disposed on different layers, and two or more light-emitting diodes may be disposed in each of the unit regions UA. The first unit region UA1 and the second unit region UA2 may be disposed alternately along each of the first direction DR1 and the second direction DR2.

Referring to FIGS. 11-13C together, a display device DD-1 according to one or more embodiments may include a CMOS wafer 10, a light-emitting structure layer 20, and a lens layer 30.

The CMOS wafer 10 may include a silicon substrate 101. The silicon substrate 101 may include source/drain regions and a gate, which define a transistor. Shallow trench isolation (STI) regions for preventing a leakage current by isolating a transistor may be defined in the silicon substrate 101.

The CMOS wafer 10 may include a contact layer 102 disposed on the silicon substrate 101. In the first region DA, the contact layer 102 may include a plurality of contact electrodes CTE. The contact electrodes CTE may be connected to the source/drain regions of the silicon substrate 101. The contact electrodes CTE may be formed through a damascene process. The contact electrodes CTE may include at least one metal such as copper and/or tungsten. The contact electrodes CTE may include a tungsten structure, a titanium layer around (e.g., surrounding) a side surface and a bottom surface of the tungsten structure, and a titanium nitride layer around (e.g., surrounding) the titanium layer. Alternatively, the contact electrodes CTE may include a copper structure, a tantalum layer around (e.g., surrounding) a side surface and a bottom surface of the copper structure, and a tantalum nitride layer around (e.g., surrounding) the tantalum layer.

The contact layer 102 may include a lower insulation layer INS-a disposed on the silicon substrate 101. The lower insulation layer INS-a may include an oxide layer such as a silicon oxide layer, a silicon nitride layer, a silicon oxynitride layer, and/or an aluminum oxide layer. A single-layered lower insulation layer INS-a is illustrated, but the lower insulation layer INS-a may be provided as a multilayer. Upper surfaces of the contact electrodes CTE may define a planar surface (or a flat surface) that is coplanar with an upper surface of the lower insulation layer INS-a.

The light-emitting structure layer 20 is disposed on the CMOS wafer 10 and includes a plurality of layers L1, L2, and L3. In the first region DA, the plurality of layers L1, L2, and L3 respectively include the plurality of light-emitting diodes LED1, LED2, and LED3.

A first layer L1 is disposed on the contact layer 102 of the CMOS wafer 10 and includes a plurality of first light-emitting diodes LED1. The plurality of first light-emitting diodes LED1 may be disposed corresponding to each of the first unit region UA1 and the second unit region UA2.

Each of the first light-emitting diodes LED1 may include a first light-emitting structure SJS1, a first lower conductive pattern LE1 disposed under the first light-emitting structure SJS1, and a first upper conductive pattern UE1 disposed on the first light-emitting structure SJS1.

The first lower conductive pattern LE1 may be directly disposed on the contact layer 102. The first lower conductive pattern LE1 may be in contact with the contact electrodes CTE of the contact layer 102. The first lower conductive pattern LE1 may include at least one metal. The first lower conductive pattern LE1 may include a metal layer. The metal layer of the first lower conductive pattern LE1 may connect the contact electrode CTE of the CMOS wafer 10 and the first lower conductive pattern LE1. The first lower conductive pattern LE1 may further include a transparent conductive oxide layer.

The first light-emitting structure SJS1 may be disposed on the first lower conductive pattern LE1 and include at least an active layer. The first light-emitting structure SJS1 may have a planar area smaller than or equal to that of the first lower conductive pattern LE1 disposed thereunder. The first light-emitting structure SJS1 may entirely overlap the first lower conductive pattern LE1.

The first upper conductive pattern UE1 may be disposed on the first light-emitting structure SJS1 and include a transparent conductive oxide. The first upper conductive pattern UE1 may have a planar area greater than or equal to that of the first light-emitting structure SJS1 disposed thereunder. The first light-emitting structure SJS1 may entirely overlap the first upper conductive pattern UE1. The first upper conductive pattern UE1 may have a planar area smaller than or equal to that of the first lower conductive pattern LE1.

The first layer L1 may further include first-layer additional conductive patterns AP1 and AP2. The first-layer additional conductive patterns AP1 and AP2 may be in contact with the contact electrodes CTE of the contact layer 102 and may be provided for electrical connection between the CMOS wafer 10 and second light-emitting diodes LED2 and third light-emitting diodes LED3 disposed thereabove. The first lower conductive pattern LE1 and the first-layer additional conductive patterns AP1 and AP2 may be disposed at the same layer. The first lower conductive pattern LE1 and the first-layer additional conductive patterns AP1 and AP2 may be formed through the same process and may include the same stacked structure and the same material. The first-layer additional conductive patterns AP1 and AP2 may include a first additional conductive pattern AP1 overlapping the second light-emitting diodes LED2 and a second additional conductive pattern AP2 overlapping the third light-emitting diodes LED3.

The first layer L1 may further include at least a first planarization layer INS1 disposed between the first light-emitting diodes LED1. The first planarization layer INS1 may overlap the unit regions UA and the boundary region BA, and may fill a region in which the first light-emitting diodes LED1 are not disposed. The first planarization layer INS1 may include an organic material. An upper surface of the first planarization layer INS1 may define a planar surface (or a flat surface) that is coplanar with an upper surface of the first upper conductive pattern UE1 of the first light-emitting diodes LED1.

A second layer L2 is disposed on the first layer L1 and includes the plurality of second light-emitting diodes LED2. The plurality of second light-emitting diodes LED2 may be disposed corresponding to the second unit region UA2. The number of the first light-emitting diodes LED1 disposed per unit area may be twice the number of the second light-emitting diodes LED2 disposed per unit area. As illustrated in FIG. 11, when a region including two first unit regions UA1 and two second unit regions UA2 is defined as a unit area region, four first light-emitting diodes LED1 and two second light-emitting diodes LED2 may be disposed in the unit area region.

Each of the second light-emitting diodes LED2 may include a second light-emitting structure SJS2, a second lower conductive pattern LE2 disposed under the second light-emitting structure SJS2, and a second upper conductive pattern UE2 disposed on the second light-emitting structure SJS2.

The second lower conductive pattern LE2 may include a transparent conductive oxide. The second lower conductive pattern LE2 may not include a metal. Unlike the first lower conductive pattern LE1, the second lower conductive pattern LE2 may not include a metal and include only the transparent conductive oxide. The second lower conductive pattern LE2 may include only the transparent conductive oxide so as not to block the light generated from the first light-emitting diode LED1 disposed thereunder.

The second light-emitting structure SJS2 may be disposed on the second lower conductive pattern LE2 and include at least an active layer. The second light-emitting structure SJS2 may have a planar area smaller than or equal to that of the second lower conductive pattern LE2 disposed thereunder. The second light-emitting structure SJS2 may entirely overlap the second lower conductive pattern LE2.

The second upper conductive pattern UE2 may be disposed on the second light-emitting structure SJS2 and include a transparent conductive oxide. The second upper conductive pattern UE2 may have a planar area greater than or equal to that of the second light-emitting structure SJS2 disposed thereunder. The second light-emitting structure SJS2 may entirely overlap the second upper conductive pattern UE2. The second upper conductive pattern UE2 may have a planar area smaller than or equal to that of the second lower conductive pattern LE2.

A planar area of each of the plurality of second light-emitting diodes LED2 may be greater than or equal to a planar area of each of the plurality of first light-emitting diodes LED1. A planar area of each of the second light-emitting structures SJS2 included in the second light-emitting diodes LED2 may be greater than or equal to a planar area of each of the first light-emitting structures SJS1 included in the first light-emitting diodes LED1.

The second layer L2 may further include a second-layer additional conductive pattern AP3. The second-layer additional conductive patterns AP3 may be provided for electrical connection between the CMOS wafer 10 and the third light-emitting diodes LED3 disposed thereabove. The second-layer additional conductive pattern AP3 and the second lower conductive pattern LE2 may be disposed at the same layer. The second-layer additional conductive pattern AP3 and the second lower conductive pattern LE2 may be formed through the same process and include the same stacked structure and the same material. The second-layer additional conductive pattern AP3 may at least partially overlap the third light-emitting diodes LED3.

The second layer L2 may further include at least a second planarization layer INS2 disposed between the second light-emitting diodes LED2. The second planarization layer INS2 may overlap the unit regions UA and the boundary region BA, and may fill a region in which the second light-emitting diodes LED2 are not disposed. The second planarization layer INS2 may include an organic material. An upper surface of the second planarization layer INS2 may define a planar surface (or a flat surface) that is coplanar with an upper surface of the second upper conductive pattern UE2 of the second light-emitting diodes LED2.

A third layer L3 is disposed on the second layer L2 and includes the plurality of third light-emitting diodes LED3. The plurality of third light-emitting diodes LED3 may be disposed corresponding to the first unit region UA1. The number of the first light-emitting diodes LED1 disposed per unit area may be twice the number of the third light-emitting diodes LED3 disposed per unit area. As illustrated in FIG. 11, when a region including two first unit regions UA1 and two second unit regions UA2 is defined as a unit area region, two third light-emitting diodes LED3 and four first light-emitting diodes LED1 may be disposed in the unit area region.

Each of the third light-emitting diodes LED3 may include a third light-emitting structure SJS3, a third lower conductive pattern LE3 disposed under the third light-emitting structure SJS3, and a third upper conductive pattern UE3 disposed on the third light-emitting structure SJS3.

The third lower conductive pattern LE3 may include a transparent conductive oxide. The third lower conductive pattern LE3 may not include a metal. Unlike the first lower conductive pattern LE1, the third lower conductive pattern LE3 may not include a metal and include only the transparent conductive oxide. The third lower conductive pattern LE3 may include only the transparent conductive oxide so as not to block the light generated from the first light-emitting diode LED1 and the second light-emitting diode LED2 disposed thereunder.

The third light-emitting structure SJS3 may be disposed on the third lower conductive pattern LE3 and include at least an active layer. The third light-emitting structure SJS3 may have a planar area smaller than or equal to that of the third lower conductive pattern LE3 disposed thereunder. The third light-emitting structure SJS3 may entirely overlap the third lower conductive pattern LE3.

The third upper conductive pattern UE3 may be disposed on the third light-emitting structure SJS3 and include a transparent conductive oxide. The third upper conductive pattern UE3 may have a planar area greater than or equal to that of the third light-emitting structure SJS3 disposed thereunder. The third light-emitting structure SJS3 may entirely overlap the third upper conductive pattern UE3. The third upper conductive pattern UE3 may have a planar area smaller than or equal to that of the third lower conductive pattern LE3.

A planar area of each of the plurality of third light-emitting diodes LED3 may be greater than or equal to a planar area of each of the plurality of second light-emitting diodes LED2. A planar area of each of the third light-emitting structures SJS3 included in the third light-emitting diodes LED3 may be greater than or equal to a planar area of each of the second light-emitting structures SJS2 included in the second light-emitting diodes LED2.

The third layer L3 may further include at least a third planarization layer INS3 disposed between the third light-emitting diodes LED3. The third planarization layer INS3 may overlap the unit regions UA and the boundary region BA, and may fill a region in which the third light-emitting diodes LED3 are not disposed. The third planarization layer INS3 may include an organic material. An upper surface of the third planarization layer INS3 may define a planar surface (or a flat surface) that is coplanar with an upper surface of the third upper conductive pattern UE3 of the third light-emitting diodes LED3.

The light-emitting structure layer 20 further includes a first electrode pattern EP1, and the first electrode pattern EP1 has a mesh structure on a plane (e.g., in a plan view). The first electrode pattern EP1 may include sub-electrode patterns EP1-S1, EP1-S2, and EP1-S3 disposed respectively corresponding to the plurality of layers L1, L2, and L3. In this specification, one of the sub-electrode patterns EP1-S1, EP1-S2, and EP1-S3 may be referred to as an “electrode pattern”, and the rest may be referred to as an “additional electrode pattern”.

The sub-electrode patterns EP1-S1, EP1-S2, and EP1-S3 may be respectively connected to the plurality of light-emitting diodes LED1, LED2, and LED3 corresponding thereto. In one or more embodiments, a first sub-electrode pattern EP1-S1 disposed within the first layer L1 may be connected to the first upper conductive pattern UE1 of the first light-emitting diodes LED1, a second sub-electrode pattern EP1-S2 disposed within the second layer L2 may be connected to the second upper conductive pattern UE2 of the second light-emitting diodes LED2, and a third sub-electrode pattern EP1-S3 disposed within the third layer L3 may be connected to the third upper conductive pattern UE3 of the third light-emitting diodes LED3. The first sub-electrode pattern EP1-S1 may be in contact with a lower portion of the first upper conductive pattern UE1, the second sub-electrode pattern EP1-S2 may be in contact with a lower portion of the second upper conductive pattern UE2, and the third sub-electrode pattern EP1-S3 may be in contact with a lower portion of the third upper conductive pattern UE3.

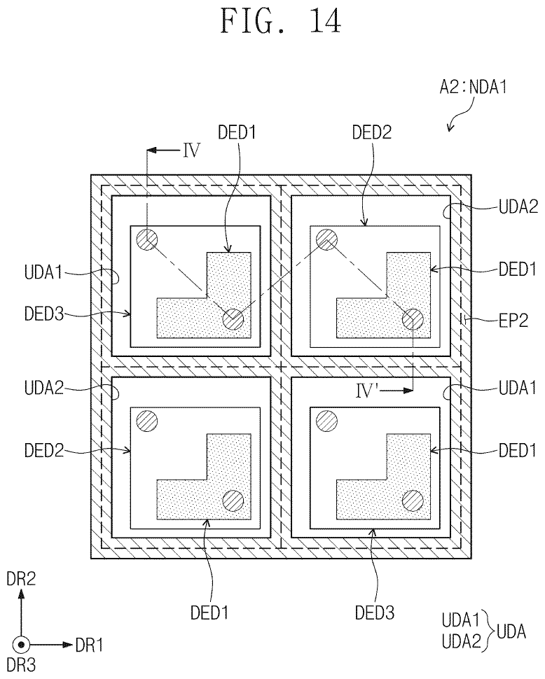

Each of the sub-electrode patterns EP1-S1, EP1-S2, and EP1-S3 may not overlap, on a plane (e.g., in a plan view), each of the first light-emitting structure SJS1, the second light-emitting structure SJS2, and the third light-emitting structure SJS3. Each of the sub-electrode patterns EP1-S1, EP1-S2, and EP1-S3 may be disposed overlapping the boundary region BA. In the first region DA, the sub-electrode patterns EP1-S1, EP1-S2, and EP1-S3 may not connect the light-emitting diodes LED1, LED2, and LED3 respectively disposed on the plurality of layers L1, L2, and L3. The light-emitting diodes LED1, LED2, and LED3 respectively disposed on the plurality of layers L1, L2, and L3 may be electrically connected to each other by the sub-electrode patterns EP1-S1, EP1-S2, and EP1-S3 disposed in the second region NDA1 (see FIG. 14) to be described later.

The light-emitting structure layer 20 may further include optical layers DBR1 and DBR2. The optical layers DBR1 and DBR2 may be disposed between the first layer L1 and the second layer L2 and/or between the second layer L2 and the third layer L3. For example, the optical layers DBR1 and DBR2 may include a first optical layer DBR1 disposed between the first layer L1 and the second layer L2, and a second optical layer DBR2 disposed between the second layer L2 and the third layer L3. In one or more embodiments, at least one of the first optical layer DBR1 or the second optical layer DBR2 may be omitted.

The light-emitting structure layer 20 may further include connection lines CL2-1, CL3-1, and CL3-2. Each of the connection lines CL2-1, CL3-1, and CL3-2 may be provided for electrical connection between the CMOS wafer 10 and the second light-emitting diodes LED2 and the third light-emitting diodes LED3. Each of the connection lines CL2-1, CL3-1, and CL3-2 may be formed through a damascene process. The connection lines CL2-1, CL3-1, and CL3-2 may each include at least one metal such as copper and/or tungsten.

In one or more embodiments, (2-1)-th connection lines CL2-1 may be disposed under the respective second light-emitting diodes LED2. The (2-1)-th connection lines CL2-1 may overlap the second light-emitting diodes LED2 on a plane (in a plan view), and may be provided to electrically connect the CMOS wafer 10 and the second light-emitting diodes LED2. The second lower conductive pattern LE2 of the second light-emitting diode LED2 may be electrically connected to the CMOS wafer 10 via the (2-1)-th connection line CL2-1 and the first additional conductive pattern AP1 which are sequentially disposed therebetween.

Third connection lines CL3 may be disposed under the respective third light-emitting diodes LED3. The third connection lines CL3 may overlap the third light-emitting diodes LED3 on a plane (e.g., in a plan view), and may be provided to electrically connect the CMOS wafer and the third light-emitting diodes LED3. The third connection line CL3 may include a (3-2)-th connection line CL3-2 disposed between the third lower conductive pattern LE3 of the third light-emitting diode LED3 and the third additional conductive pattern AP3, and a (3-1)-th connection line CL3-1 disposed between the third additional conductive pattern AP3 and the second additional conductive pattern AP2. The third lower conductive pattern LE3 of the third light-emitting diode LED3 may be electrically connected to the CMOS wafer 10 via the second additional conductive pattern AP2, the (3-1)-th connection line CL3-1, the third additional conductive pattern AP3, and the (3-2)-th connection line CL3-2, which are disposed sequentially therebetween.

The first light-emitting diodes LED1, the second light-emitting diodes LED2, and the third light-emitting diodes LED3 may not at least partially overlap each other on a plane (e.g., in a plan view). In one or more embodiments, a portion of each of the first light-emitting diodes LED1 may overlap the second light-emitting diodes LED2 on a plane (e.g., in a plan view) and the rest may not overlap the second light-emitting diodes LED2. In one or more embodiments, as shown in FIG. 12, each of the second light-emitting diodes LED2 may not overlap the third light-emitting diodes LED3 on a plane (e.g., in a plan view). In one or more other embodiments, each of the first light-emitting diodes LED1 may not overlap the third light-emitting diodes LED3 on a plane (e.g., in a plan view). In one or more embodiments, as shown in FIG. 12, a portion of each of the first light-emitting diodes LED1 may overlap each of the second light-emitting diodes LED2 or the third light-emitting diodes LED3 on a plane (e.g., in a plan view) and the rest may not overlap the second light-emitting diodes LED2 or the third light-emitting diodes LED3. In one or more other embodiments, a portion of each of the second light-emitting diodes LED2 may overlap each of the first light-emitting diodes LED1 or the third light-emitting diodes LED3 on a plane (e.g., in a plan view) and the rest may not overlap each of the first light-emitting diodes LED1 or the third light-emitting diodes LED3. In one or more embodiments, as shown in FIG. 12, a portion of each of the third light-emitting diodes LED3 may overlap the first light-emitting diodes LED1 on a plane (e.g., in a plan view) and the rest may not overlap the first light-emitting diodes LED1. In one or more embodiments, a portion of each of the third light-emitting diodes LED3 may overlap the second light-emitting diodes LED2 on a plane (e.g., in a plan view) and the rest may not overlap the second light-emitting diodes LED2. In a region where being connected to the connection lines CL2-1, CL3-1, and CL3-2, the first light-emitting diodes LED1, the second light-emitting diodes LED2, and the third light-emitting diodes LED3 may each not overlap other light-emitting diodes.

In one or more embodiments, the first layer L1, the second layer L2, and the third layer L3 may each include a side surface insulation layer and a side surface reflection layer which are disposed on side surfaces of each of the plurality of light-emitting diodes LED1, LED2, and LED3.

The lens layer 30 may be disposed on the light-emitting structure layer 20 and include a plurality of lenses LS. The lens layer 30 may further include a passivation layer BS-L, which provides a base surface on which the lens LS is disposed. The passivation layer BS-L may be disposed on the third layer L3 and protect the light-emitting diodes LED1, LED2, and LED3 disposed thereunder. The passivation layer BS-L may include an organic material and/or an inorganic material.

The lens LS may be disposed to overlap at least the light-emitting diodes LED1, LED2, and LED3. As illustrated in FIG. 12, the lens LS may be disposed corresponding to each of the first unit region UA1 and the second unit region UA2. One lens LS may be provided to each first unit region UA1 and one lens LS may be provided to each second unit region UA2. The lens LS provided to the first unit region UA1 may be disposed corresponding to one first light-emitting diode LED1 and one third light-emitting diode LED3, and the lens LS provided to the second unit region UA2 may be disposed corresponding to one first light-emitting diode LED1 and one second light-emitting diode LED2. Each of the lenses LS may have a circular shape on a plane (e.g., in a plan view (e.g., each of the lenses LS may have a semi-circular shape in a cross section)) and the diameter of each of the lenses LS may be smaller than about one micrometer.

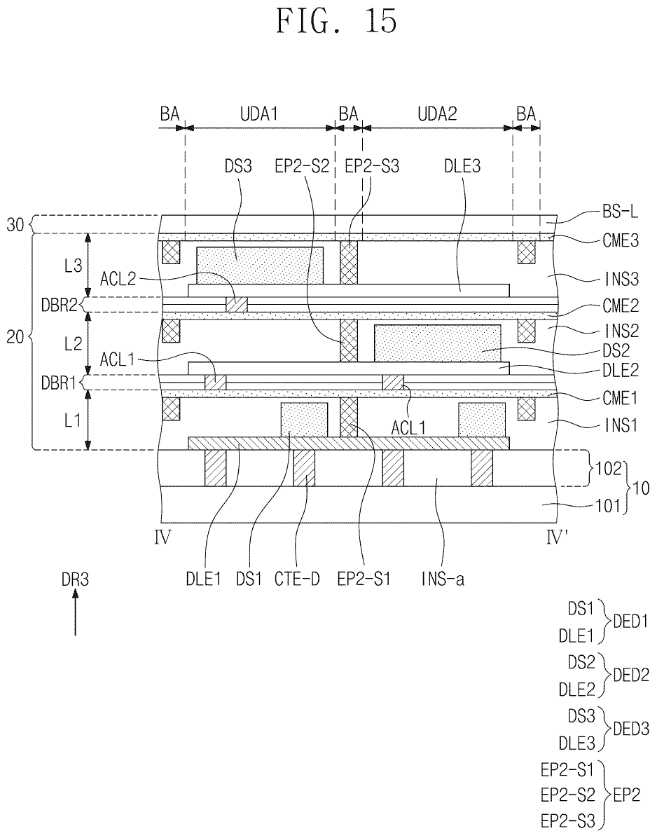

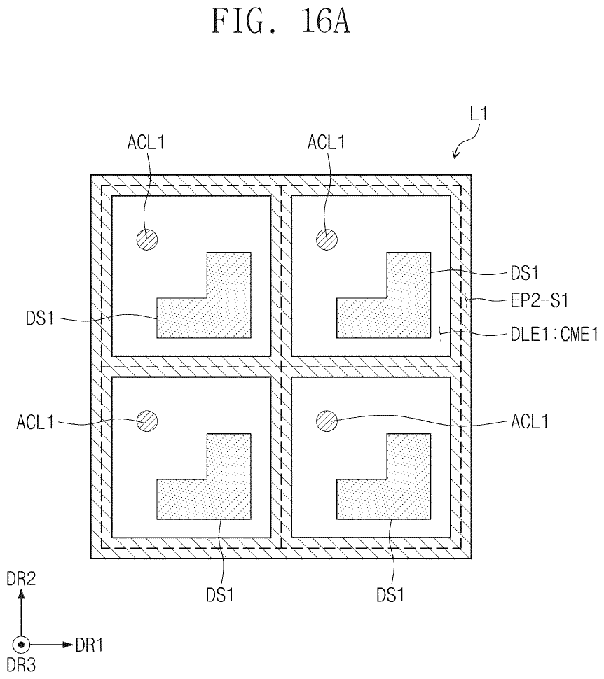

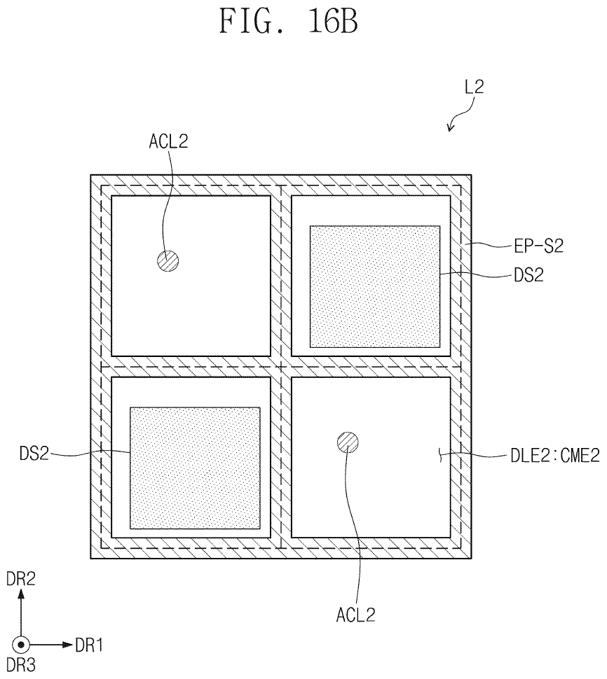

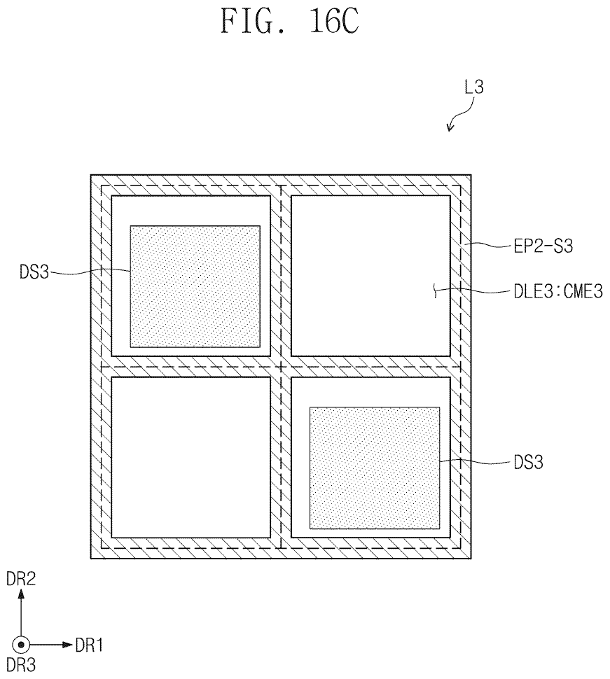

FIG. 14 is an enlarged plan view of a portion of the display device according to one or more embodiments of the present disclosure. FIG. 15 is an enlarged cross-sectional view of a portion of the display device according to one or more embodiments of the present disclosure. FIGS. 16A-16C are each a plan view of some components of the display device according to one or more embodiments of the present disclosure. FIG. 14 is an enlarged plan view of a portion A2 of the second region NDA1 illustrated in FIG. 3A. FIG. 15 is a cross-sectional view taken along the line IV-IV′ illustrated in FIG. 14. FIGS. 16A-16C are each a plan view illustrating a planar arrangement of components, from among the components illustrated in FIG. 14, disposed corresponding to the first layer L1, the second layer L2, and the third layer L3. FIGS. 14-16C illustrate a plan view and a cross-sectional view corresponding to a portion of the second region NDA1 in the display device DD-1 according to the embodiment illustrated in FIGS. 11 to 13C.

Referring to FIG. 14, the second region NDA1 may include a plurality of dummy unit regions UDA and a boundary region BA between the dummy unit regions UDA. The boundary region BA may be a region overlapping the aforementioned electrode pattern EP (see FIG. 3B). An electrode pattern, from among the electrode pattern EP (see FIG. 3B), disposed corresponding to the second region NDA1 may be referred to as a second electrode pattern EP2.

A plurality of dummy light-emitting diodes DED1, DED2, and DED3 are disposed in each of the dummy unit regions UDA. The dummy unit regions UDA may include a first dummy unit region UDA1 in which a first dummy light-emitting diode DED1 and a third dummy light-emitting diode DED3 overlap, and a second dummy unit region UDA2 in which the first dummy light-emitting diode DED1 and a second dummy light-emitting diode DED2 overlap. The first dummy light-emitting diode DED1, the second dummy light-emitting diode DED2, and the third dummy light-emitting diode DED3 are respectively disposed on different layers, and two or more dummy light-emitting diodes may be disposed in each dummy unit region UDA. The first dummy unit region UDA1 and the second dummy unit region UDA2 may be disposed alternately along each of the first direction DR1 and the second direction DR2.

Referring to FIGS. 14-16C together, the display device DD-1 according to one or more embodiments may include the CMOS wafer 10 and the light-emitting structure layer 20.

The CMOS wafer 10 may include the silicon substrate 101 and the contact layer 102 disposed on the silicon substrate 101. In the second region NDA1, the contact layer 102 may include a plurality of dummy contact electrodes CTE-D. The dummy contact electrodes CTE-D may be connected to the source/drain regions of the silicon substrate 101. The dummy contact electrodes CTE-D may be formed through a damascene process. The dummy contact electrodes CTE-D may include at least one metal such as copper and/or tungsten. The dummy contact electrodes CTE-D and the aforementioned contact electrodes CTE (see FIG. 12) may be formed through the same process and may have the same material and structure.

The contact layer 102 may include the lower insulation layer INS-a disposed on the silicon substrate 101. Upper surfaces of the dummy contact electrodes CTE-D may define a planar surface (or a flat surface) that is coplanar with an upper surface of the lower insulation layer INS-a.

The light-emitting structure layer 20 is disposed on the CMOS wafer 10 and includes the plurality of layers L1, L2, and L3. In the second region NDA1, the plurality of layers L1, L2, and L3 respectively include the plurality of dummy light-emitting diodes DED1, DED2, and DED3.

The first layer L1 is disposed on the contact layer 102 of the CMOS wafer 10 and includes the plurality of first dummy light-emitting diodes DED1. The plurality of first dummy light-emitting diodes DED1 may be disposed corresponding to both the first dummy unit region UDA1 and the second dummy unit region UDA2.

Each of the first dummy light-emitting diodes DED1 may include a first dummy structure DS1 and a first lower dummy pattern DLE1 disposed under the first dummy structure DS1.

The first lower dummy pattern DLE1 may be directly disposed on the contact layer 102. The first lower dummy pattern DLE1 may be in contact with each of the dummy contact electrodes CTE-D of the contact layer 102. The first lower dummy pattern DLE1 and the aforementioned first lower conductive pattern LE1 (see FIG. 12) may be formed through the same process and may have the same material and stacked structure. The first lower dummy pattern DLE1 and the first lower conductive pattern LE1 (see FIG. 12) may be disposed at the same layer. The first lower dummy pattern DLE1 may overlap both the first dummy unit region UDA1 and the second dummy unit region UDA2.

The first dummy structure DS1 may be disposed on the first lower dummy pattern DLE1 and include at least an active layer. The first dummy structure DS1 may have a planar area smaller than or equal to that of the first lower dummy pattern DLE1 disposed thereunder. The first dummy structure DS1 may entirely overlap the first lower dummy pattern DLE1. The first dummy structure DS1 and the aforementioned first light-emitting structure SJS1 (see FIG. 12) may be formed through the same process and may have the same material and stacked structure. The first dummy structure DS1 and the first light-emitting structure SJS1 (see FIG. 12) may be disposed at the same layer.

The first layer L1 may further include at least the first planarization layer INS1 disposed between the first dummy light-emitting diodes DED1. The first planarization layer INS1 may overlap the dummy unit regions UDA and the boundary region BA, and may fill a region in which the first dummy light-emitting diodes DED1 are not disposed. The first planarization layer INS1 may include an organic material.

The second layer L2 is disposed on the first layer L1 and includes the plurality of second dummy light-emitting diodes DED2. In one or more embodiments, as shown in FIGS. 14-15, the plurality of second dummy light-emitting diodes DED2 may be disposed corresponding to the second dummy unit region UDA2. In one or more other embodiments, the plurality of second dummy light-emitting diodes DED2 may be disposed corresponding to both the first dummy unit region UDA1 and the second dummy unit region UDA2. The number of the first dummy light-emitting diodes DED1 disposed per unit area may be twice the number of the second dummy light-emitting diodes DED2 disposed per unit area. As illustrated in FIG. 14, when a region including two first dummy unit regions UDA1 and two second dummy unit regions UDA2 is defined as a unit area region, four first dummy light-emitting diodes DED1 and two second dummy light-emitting diodes DED2 may be disposed in the unit area region.

Each of the second dummy light-emitting diodes DED2 may include a second dummy structure DS2 and a second lower dummy pattern DLE2 disposed under the second dummy structure DS2.

The second lower dummy pattern DLE2 and the aforementioned second lower conductive pattern LE2 (see FIG. 12) may be formed through the same process and may have the same material and stacked structure. The second lower dummy pattern DLE2 and the second lower conductive pattern LE2 (see FIG. 12) may be disposed at the same layer. The second lower dummy pattern DLE2 may not include a metal and include only a transparent conductive oxide. The second lower dummy pattern DLE2 may overlap both the first dummy unit region UDA1 and the second dummy unit region UDA2.

The second dummy structure DS2 may be disposed on the second lower dummy pattern DLE2 and include at least an active layer. The second dummy structure DS2 may have a planar area smaller than or equal to the second lower dummy pattern DLE2 disposed thereunder. The second dummy structure DS2 may entirely overlap the second lower dummy pattern DLE2. The second dummy structure DS2 and the aforementioned second light-emitting structure SJS2 (see FIG. 12) may be formed through the same process and may have the same material and stacked structure. The second dummy structure DS2 and the second light-emitting structure SJS2 (see FIG. 12) may be disposed at the same layer.

The second layer L2 may further include the second planarization layer INS2 disposed between the second dummy light-emitting diodes DED2. The second planarization layer INS2 may overlap the dummy unit regions UDA and the boundary region BA, and may fill a region in which the second dummy light-emitting diodes DED2 are not disposed. The second planarization layer INS2 may include an organic material.

The third layer L3 is disposed on the second layer L2 and includes the plurality of third dummy light-emitting diodes DED3. In one or more embodiments, as shown in FIGS. 14-15, the plurality of third dummy light-emitting diodes DED3 may be disposed corresponding to the first dummy unit region UDA1. In one or more other embodiments, the plurality of third dummy light-emitting diodes DED3 may be disposed corresponding to the second dummy unit region UDA2. The number of the first dummy light-emitting diodes DED1 disposed per unit area may be twice the number of the third dummy light-emitting diodes DED3 disposed per unit area. As illustrated in FIG. 14, when a region including two first dummy unit regions UDA1 and two second dummy unit regions UDA2 is defined as a unit area region, two third dummy light-emitting diodes DED3 and four first dummy light-emitting diodes DED1 may be disposed in the unit area region.

Each of the third dummy light-emitting diodes DED3 may include a third dummy structure DS3 and a third lower dummy pattern DLE3 disposed under the third dummy structure DS3.

The third lower dummy pattern DLE3 and the aforementioned third lower conductive pattern LE3 (see FIG. 12) may be formed through the same process and may have the same material and stacked structure. The third lower dummy pattern DLE3 and the third lower conductive pattern LE3 (see FIG. 12) may be disposed at the same layer. The third lower dummy pattern DLE3 may not include a metal and include only a transparent conductive oxide. The third lower dummy pattern DLE3 may overlap both the first dummy unit region UDA1 and the second dummy unit region UDA2.

The third dummy structure DS3 may be disposed on the third lower dummy pattern DLE3 and include at least an active layer. The third dummy structure DS3 may have a planar area smaller than or equal to the third lower dummy pattern DLE3 disposed thereunder. The third dummy structure DS3 may entirely overlap the third lower dummy pattern DLE3. The third dummy structure DS3 and the aforementioned third light-emitting structure SJS3 (see FIG. 12) may be formed through the same process and may have the same material and stacked structure. The third dummy structure DS3 and the third light-emitting structure SJS3 (see FIG. 12) may be disposed at the same layer.

The third layer L3 may further include at least the third planarization layer INS3 disposed between the third dummy light-emitting diodes DED3. The third planarization layer INS3 may overlap the dummy unit regions UDA and the boundary region BA, and may fill a region in which the third dummy light-emitting diodes DED3 are not disposed. The third planarization layer INS3 may include an organic material.

In the second region NDA1, the light-emitting structure layer 20 may further include a first common electrode CME1, a second common electrode CME2, and a third common electrode CME3. The first common electrode CME1 may be disposed on the first dummy light-emitting diodes DED1. The second common electrode CME2 may be disposed on the second dummy light-emitting diodes DED2. The third common electrode CME3 may be disposed on the third dummy light-emitting diodes DED3.

Referring to FIGS. 11-16C together, the first common electrode CME1, the second common electrode CME2, and the third common electrode CME3 may be electrically connected to the upper conductive patterns UE1, UE2, and UE3 of the aforementioned light-emitting diodes LED1, LED2, and LED3 in the first region DA, respectively. The first common electrode CME1 may be electrically connected to the first upper conductive pattern UE1 of the first light-emitting diode LED1. The first common electrode CME1 and the first upper conductive pattern UE1 may be disposed at the same layer, formed through the same process, and include the same material. The first common electrode CME1 and the first upper conductive pattern UE1 may have an integrated shape. The second common electrode CME2 may be electrically connected to the second upper conductive pattern UE2 of the second light-emitting diode LED2. The second common electrode CME2 and the second upper conductive pattern UE2 may be disposed at the same layer, formed through the same process, and include the same material. The second common electrode CME2 and the second upper conductive pattern UE2 may have an integrated shape. The third common electrode CME3 may be electrically connected to the third upper conductive pattern UE3 of the third light-emitting diode LED3. The third common electrode CME3 and the third upper conductive pattern UE3 may be disposed at the same layer, formed through the same process, and include the same material. The third common electrode CME3 and the third upper conductive pattern UE3 may have an integrated shape.

The first common electrode CME1, the second common electrode CME2, and the third common electrode CME3 are not connected to the first dummy light-emitting diodes DED1, the second dummy light-emitting diodes DED2, and the third light-emitting diodes DED3, respectively. The first common electrode CME1, the second common electrode CME2, and the third common electrode CME3 may each include a transparent conductive oxide.

The light-emitting structure layer 20 further includes the second electrode pattern EP2, and the second electrode pattern EP2 has a mesh structure on a plane (e.g., in a plan view). The second electrode pattern EP2 may be disposed corresponding to the boundary region BA. The second electrode pattern EP2 may not overlap, on a plane (e.g., in a plan view), each of the first dummy light-emitting diodes DED1, the second dummy light-emitting diodes DED2, and the third dummy light-emitting diodes DED3. The second electrode pattern EP2 and the aforementioned first electrode pattern EP1 may be formed through the same process and may have the same material. The second electrode pattern EP2 and the first electrode pattern EP1 may have an integrated shape.

The second electrode pattern EP2 may include sub-electrode patterns EP2-S1, EP2-S2, and EP2-S3 disposed respectively corresponding to the plurality of layers L1, L2, and L3. In this specification, one of the sub-electrode patterns EP2-S1, EP2-S2, and EP2-S3 may be referred to as an “electrode pattern”, and the rest may be referred to as an “additional electrode pattern”.

In one or more embodiments, the first sub-electrode pattern EP2-S1 disposed within the first layer L1 may electrically connect the first common electrode CME1 and the CMOS wafer 10. The first sub-electrode pattern EP2-S1 may be in contact with a lower surface of the first common electrode CME1 and an upper surface of the first lower dummy pattern DLE1 which is in contact with the CMOS wafer 10. The second sub-electrode pattern EP2-S2 disposed within the second layer L2 may electrically connect the first common electrode CME1 and the second common electrode CME2. The second sub-electrode pattern EP2-S2 may be in contact with a lower surface of the second common electrode CME2 and an upper surface of the second lower dummy pattern DLE2. The second lower dummy pattern DLE2 may be connected to the first common electrode CME1 via a first additional dummy line ACL1. The third sub-electrode pattern EP2-S3 disposed within the third layer L3 may electrically connect the second common electrode CME2 and the third common electrode CME3. The third sub-electrode pattern EP2-S3 may be in contact with a lower surface of the third common electrode CME3 and an upper surface of the third lower dummy pattern DLE3. The third lower dummy pattern DLE3 may be connected to the second common electrode CME2 via a second additional dummy line ACL2. The display device DD-1 according to one or more embodiments may have a structure in which the CMOS wafer 10, the first common electrode CME1, the second common electrode CME2, and the third common electrode CME3 are electrically connected via the sub-electrode patterns EP2-S1, EP2-S2, and EP2-S3 and the additional dummy lines ACL1 and ACL2. Accordingly, the upper conductive patterns UE1, UE2, and UE3 of the light-emitting diodes LED1, LED2, and LED3 in the first region DA, which are integrally formed with the first common electrode CME1, the second common electrode CME2, and the third common electrode CME3, respectively, may be electrically connected to each other.

The light-emitting structure layer 20 may further include the optical layers DBR1 and DBR2. The optical layers DBR1 and DBR2 may be disposed between the first layer L1 and the second layer L2 and/or between the second layer L2 and the third layer L3. The optical layers DBR1 and DBR2 may include, for example, the first optical layer DBR1 disposed between the first layer L1 and the second layer L2, and the second optical layer DBR2 disposed between the second layer L2 and the third layer L3. At least one of the first optical layer DBR1 or the second optical layer DBR2 may be omitted.

The first dummy light-emitting diodes DED1, the second dummy light-emitting diodes DED2, and the third dummy light-emitting diodes DED3 may not at least partially overlap each other on a plane (e.g. in a plan view). A portion of each of the first dummy light-emitting diodes DED1 may overlap the second dummy light-emitting diodes DED2 on a plane (e.g. in a plan view) and the rest may not overlap the second dummy light-emitting diodes DED2.

In one or more embodiments, the first layer L1, the second layer L2, and the third layer L3 may each include a side surface insulation layer and a side surface reflection layer which are disposed on side surfaces of each of the plurality of dummy light-emitting diodes DED1, DED2, and DED3.

Unlike the first region DA, the lens disposed on the light-emitting structure layer 20 may be omitted in the second region NDA1. Because the dummy light-emitting diodes DED1, DED2, and DED3 disposed in the second region NDA1 do not substantially generate light, the lenses disposed thereon may be omitted. However, the present disclosure is not limited thereto, and lenses may be disposed on the light-emitting structure layer 20 in the second region NDA1 to correspond to the dummy unit regions UDA.

FIGS. 14-16C each illustrates a planar arrangement and cross-sectional stacked structure of the portion A2 of the second region NDA1 illustrated in FIG. 3A, but the same planar arrangement and cross-sectional stacked structure may also be applied to a portion A3 of the pad region PDA illustrated in FIG. 3A. Portions of the common electrodes CME1, CME2, and CME3 disposed corresponding to the pad region PDA may correspond to the voltage transfer electrode VTE illustrated in FIG. 3A.

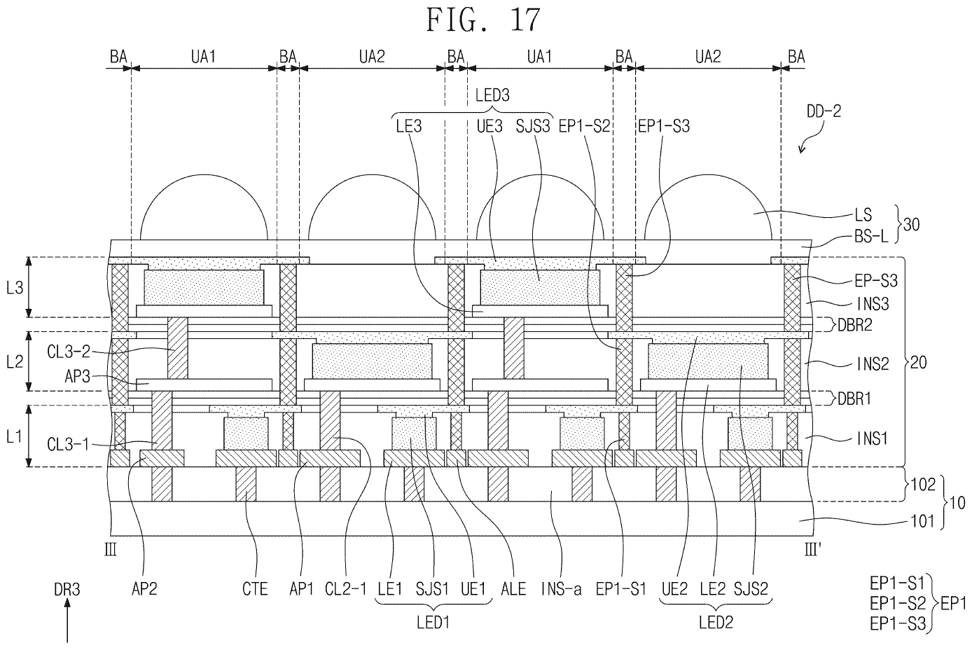

FIG. 17 is an enlarged plan view of a portion of a display device according to one or more embodiments of the present disclosure. FIG. 17 illustrates, as similar to the cross section of FIG. 12, a cross section, taken along the line III-III′ illustrated in FIG. 11, of a display device DD-2 according to one or more embodiments that is different from the display device DD-1 according to the embodiment illustrated in FIG. 12. Hereinafter, when describing the display device DD-2 according to one or more embodiments with reference to FIG. 17, components described with reference to FIG. 12, etc., will be denoted as the same reference numerals or symbols, detailed description thereof will be omitted, and differences between the display device DD-1 illustrated in FIG. 12 will be mainly explained.

Referring to FIG. 17, a light-emitting structure layer 20 in the display device DD-2 according to one or more embodiments includes a first electrode pattern EP1, and the first electrode pattern EP1 has a mesh structure on a plane (e.g., in a plan view). The first electrode pattern EP1 may include sub-electrode patterns EP1-S1, EP1-S2, and EP1-S3 disposed respectively corresponding to plurality of layers L1, L2, and L3. In this specification, one of the sub-electrode patterns EP1-S1, EP1-S2, or EP1-S3 may be referred to as an “electrode pattern”, and the rest may be referred to as an “additional electrode pattern”.

Unlike the embodiment illustrated in FIG. 12, in a first region DA (see FIG. 11) of the display device DD-2 according to one or more embodiments, the sub-electrode patterns EP1-S1, EP1-S2, and EP1-S3 included in the light-emitting structure layer 20 may electrically connect light-emitting diodes LED1, LED2, and LED3 disposed on different layers, respectively.

A first sub-electrode pattern EP1-S1 may be connected to a first upper conductive pattern UE1 of first light-emitting diodes LED1 and an additional lower conductive pattern ALE. The additional lower conductive pattern ALE and a first lower conductive pattern LE1 may be disposed at the same layer, include the same material, and formed through the same process. The additional lower conductive pattern ALE may be electrically connected to a CMOS wafer 10. The first sub-electrode pattern EP1-S1 may be in contact with the first upper conductive pattern UE1 and the additional lower conductive pattern ALE, and thus electrically connect the CMOS wafer 10 and the first upper conductive pattern UE1. A second sub-electrode pattern EP1-S2 may be connected to a second upper conductive pattern UE2 of second light-emitting diodes LED2 and connected to the first upper conductive pattern UE1. The second sub-electrode pattern EP1-S2 may be in contact with the second upper conductive pattern UE2 and the first upper conductive pattern UE1, and thus electrically connect the first upper conductive pattern UE1 and the second upper conductive pattern UE2. A third sub-electrode pattern EP1-S3 may be connected to a third upper conductive pattern UE3 of third light-emitting diodes LED3 and connected to the second upper conductive pattern UE2. The third sub-electrode pattern EP1-S3 may be in contact with the third upper conductive pattern UE3 and the second upper conductive pattern UE2, and thus electrically connect the second upper conductive pattern UE2 and the third upper conductive pattern UE3.

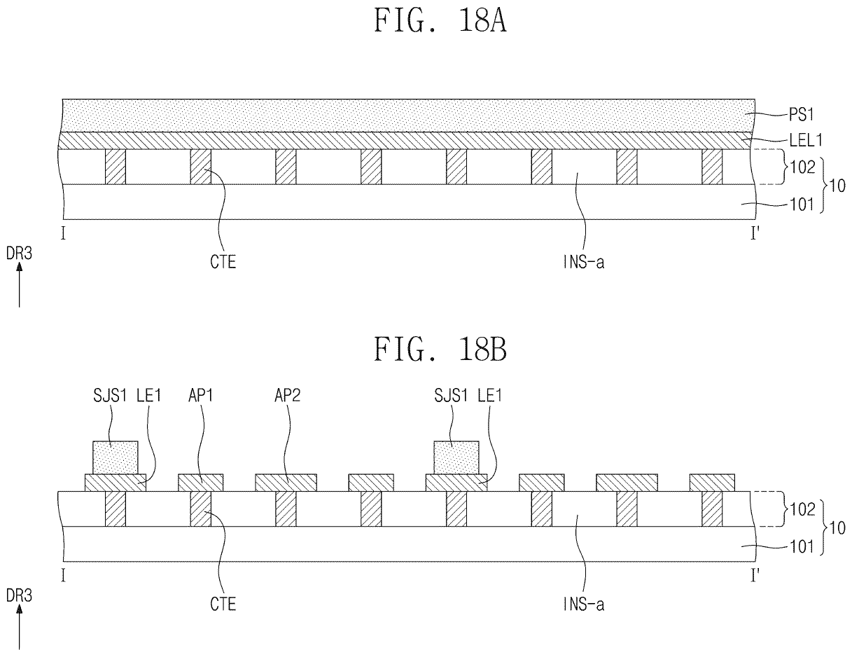

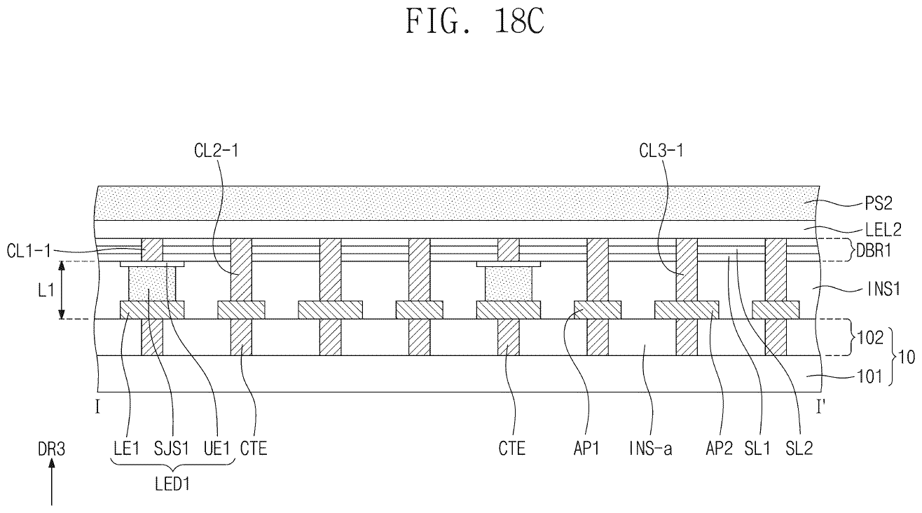

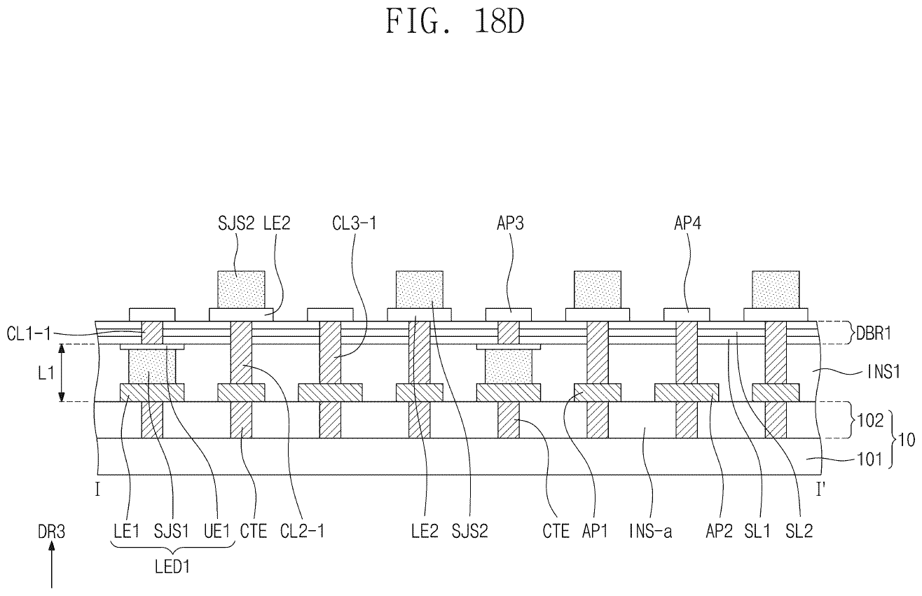

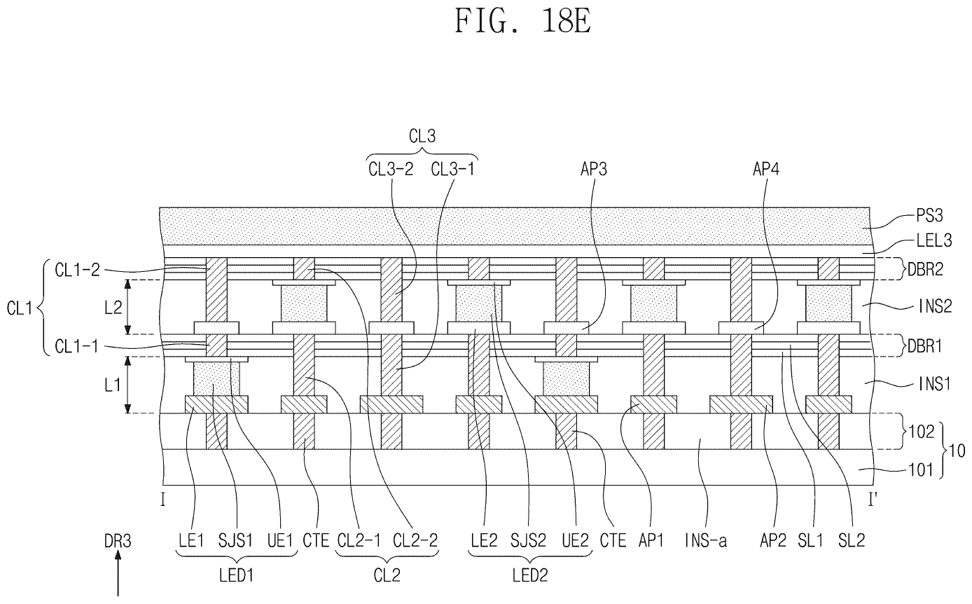

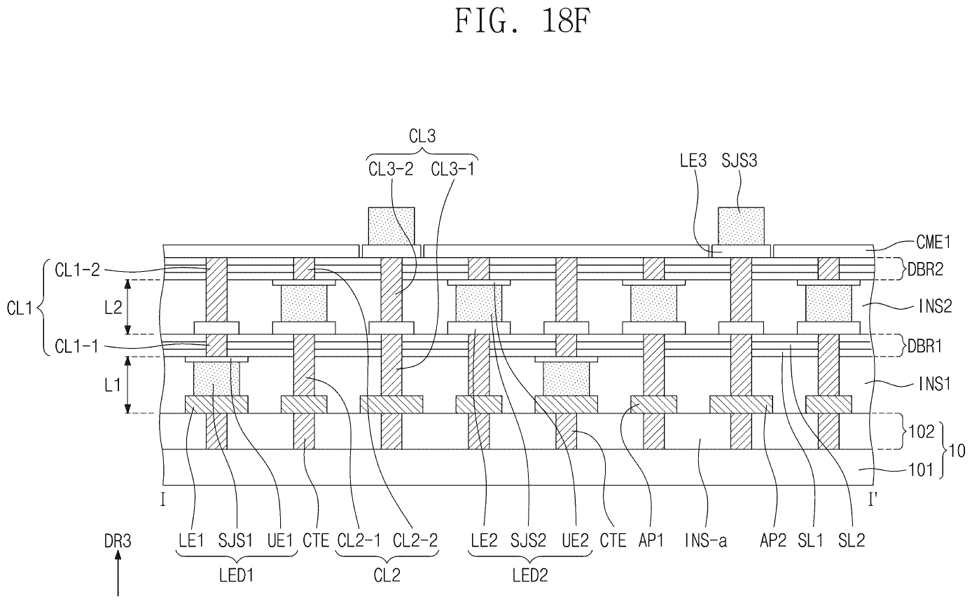

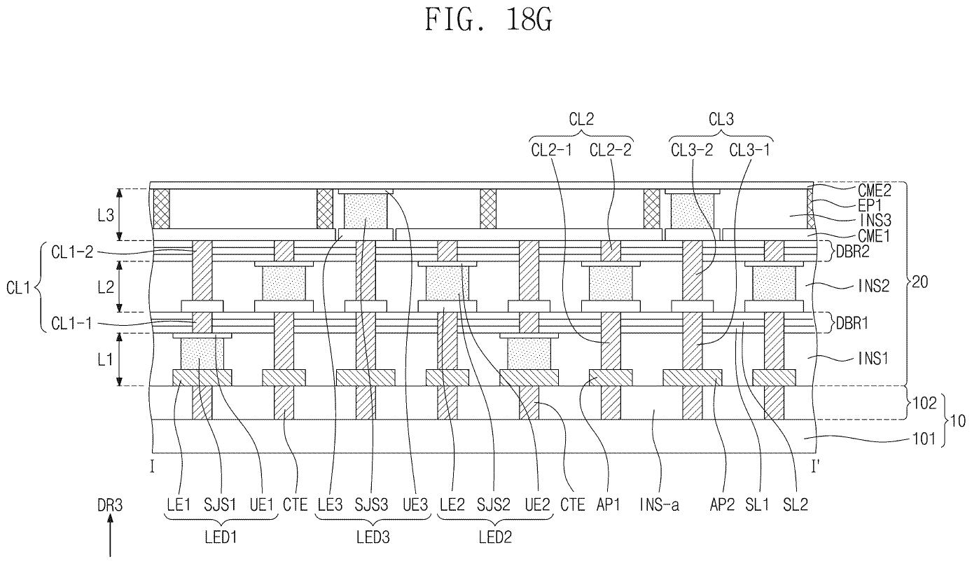

FIGS. 18A-18G are cross-sectional views sequentially illustrating some steps of a manufacturing method of a display device according to one or more embodiments of the present disclosure. FIGS. 18A-18G illustrate each step of a manufacturing method of a display device DD according to one or more embodiments in the cross-section of FIG. 6. Hereinafter, with regard to the descriptions of the manufacturing method of a display device according to one or more embodiments described with reference to FIGS. 18A-18G, the components described with reference to FIGS. 5-17 will be denoted as the same reference numerals or symbols, and detailed descriptions thereof may be omitted.

The method for manufacturing a display device according to one or more embodiments includes: forming a first epitaxial layer on a CMOS wafer and then forming a plurality of first light-emitting structures through patterning; forming a second epitaxial layer on the plurality of first light-emitting structures and then forming a plurality of second light-emitting structures through patterning; forming a third epitaxial layer on the plurality of second light-emitting structures and then forming a plurality of third light-emitting structures through patterning; forming a first common electrode electrically connected to at least some of the plurality of first light-emitting structures, the plurality of second light-emitting structures, and/or the plurality of third light-emitting structures; forming a second common electrode electrically connected to at least some of the rest of the plurality of first light-emitting structures, the plurality of second light-emitting structures, and the plurality of third light-emitting structures, which are not connected to the first common electrode; and forming an electrode pattern having a mesh structure on a plane (e.g., on a plan view), and electrically connecting the first common electrode and the second common electrode. At least one of the steps of the forming of the first common electrode and the forming of the second common electrode may be provided between the steps of forming the first to third light-emitting structures. For example, the forming of the first common electrode may be performed between the forming of the first light-emitting structure and the forming of the second light-emitting structure. The forming of the second common electrode may be performed between the forming of the second light-emitting structure and the forming of the third light-emitting structure.

Referring to FIG. 18A, the method for manufacturing a display device according to one or more embodiments includes the forming of a first epitaxial layer PS1 on a CMOS wafer 10. The CMOS wafer 10 may include a silicon substrate 101. The silicon substrate 101 may include a source/drain regions and a gate which define a transistor. The CMOS wafer 10 may include a contact layer 102 disposed on the silicon substrate 101. The contact layer 102 may include a plurality of contact electrodes CTE. The contact layer 102 may include a lower insulation layer INS-a disposed on the silicon substrate 101.

The first epitaxial layer PS1 is a preliminary layer provided for forming a plurality of first light-emitting structures SJS1 (see FIG. 18B) and may be a gallium nitride (GaN) epiwafer. The first epitaxial layer PS1 may be provided as a common layer on the CMOS wafer 10.

A first lower conductive layer LEL1 may be formed on the CMOS wafer 10, before the forming of the first epitaxial layer PS1. The first lower conductive layer LEL1 may include at least one metal. The first lower conductive layer LEL1 may include a metal layer. The metal layer of the first lower conductive layer LEL1 may be provided to connect the contact electrode CTE of the CMOS wafer 10 and the first lower conductive layer LEL1. The first lower conductive layer LEL1 may further include a transparent conductive oxide layer. The first lower conductive layer LEL1 may be provided as a common layer on the CMOS wafer 10. The first epitaxial layer PS1 may be formed so as to be directly disposed on the first lower conductive layer LEL1.

Referring to FIGS. 18A and 18B together, a plurality of first light-emitting structures SJS1 are formed by patterning the first epitaxial layer PS1. The first light-emitting structure SJS1 may include at least an active layer.

After the plurality of first light-emitting structures SJS1 are formed by patterning the first epitaxial layer PS1, the first lower conductive pattern LE1 may be formed by patterning the first lower conductive layer LEL1. The first lower conductive pattern LE1 may be formed through patterning, after the first light-emitting structure SJS1 is formed, and the first lower conductive pattern LE1 may have a planar area greater than or equal to that of the first light-emitting structure SJS1 formed thereon. In the patterning of the first lower conductive layer LEL1, first-layer additional conductive patterns AP1 and AP2 may be formed together in addition to the first lower conductive pattern LE1. The first-layer additional conductive patterns AP1 and AP2 may include a first additional conductive pattern AP1 and a second additional conductive pattern AP2.

Referring to FIGS. 18B and 18C together, a first layer L1 may be formed by forming a first upper conductive pattern UE1 on the first light-emitting structure SJS1 and forming a first planarization layer INS1 on the CMOS wafer 10. The first upper conductive pattern UE1 may be formed on the first light-emitting structure SJS1 and include a transparent conductive oxide. The first upper conductive pattern UE1 may have a planar area greater than or equal to that of the first light-emitting structure SJS1 disposed thereunder. The first planarization layer INS1 may be formed to fill a region in which first light-emitting diodes LED1 are not disposed. After the first planarization layer INS1 is formed, the first upper conductive pattern UE1 may be formed by depositing a transparent conductive oxide as a common layer and then patterning the same.

Then, a first optical layer DBR1 may be formed on the first upper conductive pattern UE1 and the first planarization layer INS1. The first optical layer DBR1 may have a structure in which sub layers having different refractive indexes are formed alternately. The first optical layer DBR1 may reflect light of a specific wavelength and transmit light of other wavelengths. For example, the first optical layer DBR1 may transmit light of a wavelength emitted from the first light-emitting diode LED1 and reflect light of a wavelength emitted from a second light-emitting diode LED2 (see FIG. 18E) and a third light-emitting diode LED3 (see FIG. 18G) which are to be described later.

Thereafter, first layer connection lines such as a (1-1)-th connection line CL1-1, a (2-1)-th connection line CL2-1, and a (3-1)-th connection line CL3-1 may be formed. The (1-1)-th connection line CL1-1, the (2-1)-th connection line CL2-1, and the (3-1)-th connection line CL3-1 may be in contact with underlying conductive patterns through contact holes penetrating the first planarization layer INS1, the first optical layer DBR1, etc. The (1-1)-th connection line CL1-1 may be in contact with the first upper conductive pattern UE1 by penetrating the first optical layer DBR1. The (2-1)-th connection line CL2-1 may be in contact with the first additional conductive pattern AP1 by penetrating the first planarization layer INS1 and the first optical layer DBR1. The (3-1)-th connection line CL3-1 may be in contact with the second additional conductive pattern AP2 by penetrating the first planarization layer INS1 and the first optical layer DBR1.

The method for manufacturing a display device according to one or more embodiments includes the forming of the second epitaxial layer PS2 on the plurality of first light-emitting structures SJS1. The second epitaxial layer PS2 may be formed on the first layer L1 which includes the first light-emitting structure SJS1.

The second epitaxial layer PS2 is a preliminary layer provided for forming a plurality of second light-emitting structures SJS2 (see FIG. 18D) and may be a gallium nitride (GaN) epiwafer. The second epitaxial layer PS2 may be provided as a common layer on the first layer L1.

A second lower conductive layer LEL2 may be formed on the first layer L1, before the forming of the second epitaxial layer PS2. The second lower conductive layer LEL2 may include a transparent conductive oxide. The second lower conductive layer LEL2 may not include a metal. Unlike the first lower conductive layer LEL1, the second lower conductive layer LEL2 may not include a metal and include only the transparent conductive oxide. The second lower conductive layer LEL2 may include only the transparent conductive oxide so as not to block the light generated from the first light-emitting diode LED1 disposed thereunder. The second lower conductive layer LEL2 may be provided as a common layer on the first layer L1. The second epitaxial layer PS2 may be formed so as to be directly disposed on the second lower conductive layer LEL2.

Referring to FIGS. 18C and 18D together, a plurality of second light-emitting structures SJS2 are formed by patterning the second epitaxial layer PS2. The second light-emitting structure SJS2 may include at least an active layer.

After the plurality of second light-emitting structures SJS2 are formed by patterning the second epitaxial layer PS2, a second lower conductive pattern LE2 may be formed by patterning the second lower conductive layer LEL2. The second lower conductive pattern LE2 may be formed through patterning, after the second light-emitting structure SJS2 is formed, and the second lower conductive pattern LE2 may have a planar area greater than or equal to that of the second light-emitting structure SJS2 formed thereon. In the patterning of the second lower conductive layer LEL2, second-layer additional conductive patterns AP3 and AP4 may be formed together in addition to the second lower conductive pattern LE2. The second-layer additional conductive patterns AP3 and AP4 may include a third additional conductive pattern AP3 and a fourth additional conductive pattern AP4.

Referring to FIGS. 18D and 18E together, a second layer L2 may be formed by forming a second upper conductive pattern UE2 on the second light-emitting structure SJS2 and forming a second planarization layer INS2 on the first planarization layer INS1. The second upper conductive pattern UE2 may be formed on the second light-emitting structure SJS2 and include a transparent conductive oxide. The second upper conductive pattern UE2 may have a planar area greater than or equal to that of the second light-emitting structure SJS2 disposed thereunder. The second planarization layer INS2 may be formed to fill a region in which second light-emitting diodes LED2 are not disposed. After the second planarization layer INS2 is formed, the second upper conductive pattern UE2 may be formed by depositing a transparent conductive oxide as a common layer and then patterning the same.

Afterwards, a second optical layer DBR2 may be formed on the second upper conductive pattern UE2 and the second planarization layer INS2. The second optical layer DBR2 may have a structure in which sub layers having different refractive indexes are formed alternately. The second optical layer DBR2 may reflect light of a specific wavelength and transmit light of other wavelengths. For example, the second optical layer DBR2 may transmit light of a wavelength emitted from the first light-emitting diode LED1 and the second light-emitting diode LED2, and reflect light of a wavelength emitted from the third light-emitting diode LED3 (see FIG. 18G) which is to be described later.

Thereafter, second layer connection lines such as a (1-2)-th connection line CL1-2, a (2-2)-th connection line CL2-2, and a (3-2)-th connection line CL3-2 may be formed. The (1-2)-th connection line CL1-2, the (2-2)-th connection line CL2-2, and the (3-2)-th connection line CL3-2 may be in contact with underlying conductive patterns through contact holes penetrating the second planarization layer INS2, the second optical layer DBR2, etc. The (1-2)-th connection line CL1-2 may be in contact with the third additional conductive pattern AP3 by penetrating the second optical layer DBR2 and the second planarization layer INS2. The (2-2)-th connection line CL2-2 may be in contact with the second upper conductive pattern UE2 by penetrating the second optical layer DBR2. The (3-2)-th connection line CL3-2 may be in contact with the fourth additional conductive pattern AP4 by penetrating the second planarization layer INS2 and the second optical layer DBR2.

The method for manufacturing a display device according to one or more embodiments includes the forming of the third epitaxial layer PS3 on the plurality of second light-emitting structures SJS2. The third epitaxial layer PS3 may be formed on the second layer L2 which includes the second light-emitting structure SJS2.

The third epitaxial layer PS3 is a preliminary layer for forming a plurality of third light-emitting structures SJS3 (see FIG. 18F) and may be a gallium nitride (GaN) epiwafer. The third epitaxial layer PS3 may be provided as a common layer on the second layer L2.

A third lower conductive layer LEL3 may be formed on the second layer L2, before the forming of the third epitaxial layer PS3. The third lower conductive layer LEL3 may include a transparent conductive oxide. The third lower conductive layer LEL3 may not include a metal. Unlike the second lower conductive layer LEL2, the third lower conductive layer LEL3 may not include a metal and include only the transparent conductive oxide. The third lower conductive layer LEL3 may include only the transparent conductive oxide so as not to block the light generated from the second light-emitting diode LED2 disposed thereunder. The third lower conductive layer LEL3 may be provided as a common layer on the second layer L2. The third epitaxial layer PS3 may be formed so as to be directly disposed on the third lower conductive layer LEL3.

Referring to FIGS. 18E and 18F together, the plurality of third light-emitting structures SJS3 are formed by patterning the third epitaxial layer PS3. The third light-emitting structure SJS3 may include at least an active layer.

After the plurality of third light-emitting structures SJS3 are formed by patterning the third epitaxial layer PS3, the third lower conductive pattern LE3 may be formed by patterning the third lower conductive layer LEL3. The third lower conductive pattern LE3 may be formed through patterning, after the third light-emitting structure SJS3 is formed, and the third lower conductive pattern LE3 may have a planar area greater than or equal to that of the third light-emitting structure SJS3 formed thereon. In the patterning of the third lower conductive layer LEL3, a first common electrode CME1 may be formed together in addition to the third lower conductive pattern LE3.

Referring to FIGS. 18F and 18G together, a third layer L3 may be formed by forming a third planarization layer INS3, a first electrode pattern EP1, and a second common electrode CME2 on the third light-emitting structure SJS3.

The third planarization layer INS3 may be formed to fill a region in which third light-emitting diodes LED3 are not disposed. After the third planarization layer INS3 is formed, the third upper conductive pattern UE2 may be formed and the first electrode pattern EP1 may be formed to be in contact with the first common electrode CME1 thereunder, through a contact hole penetrating the third planarization layer INS3. The first electrode pattern EP1 may be formed to have a mesh structure on a plane.

After the third planarization layer INS3 and the first electrode pattern EP1 are formed, the second common electrode CME2 is formed on the third planarization layer INS3 and the first electrode pattern EP1. The second common electrode CME2 may be formed to be in contact with the first electrode pattern EP1 and may be electrically connected to the first common electrode CME1 disposed below, via the first electrode pattern EP1. The second common electrode CME2 may be formed to be partially in contact with the third upper conductive pattern UE3 of the third light-emitting diode LED3.

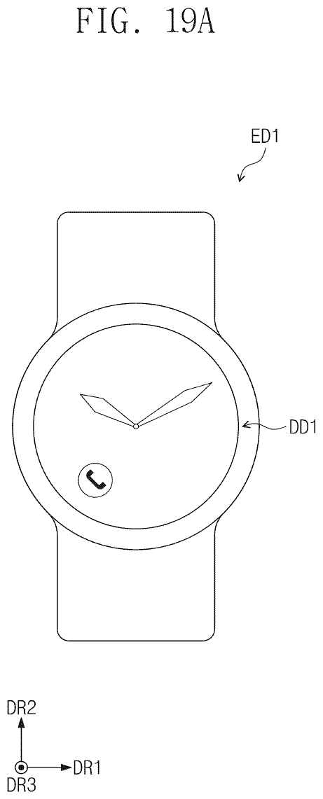

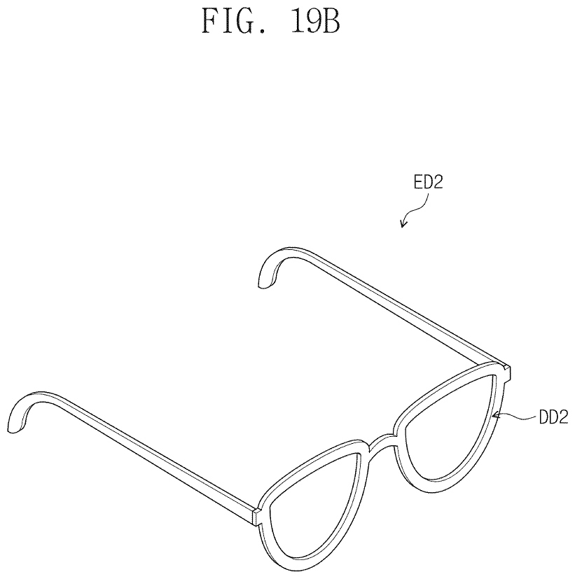

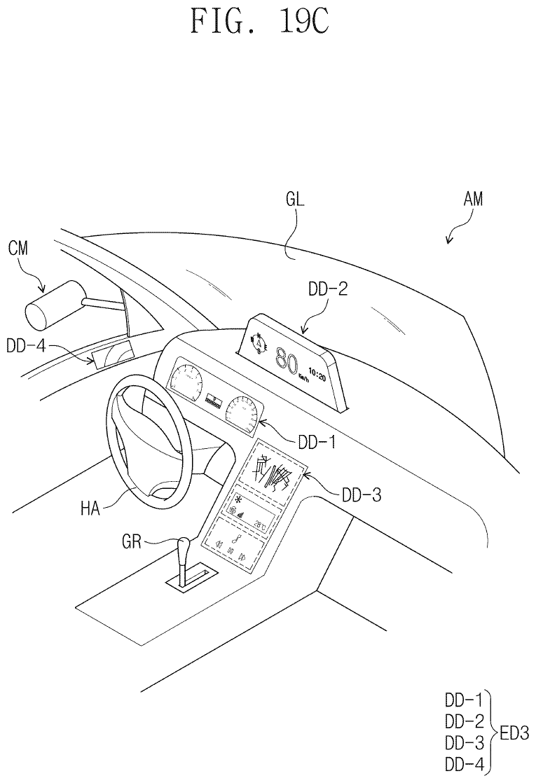

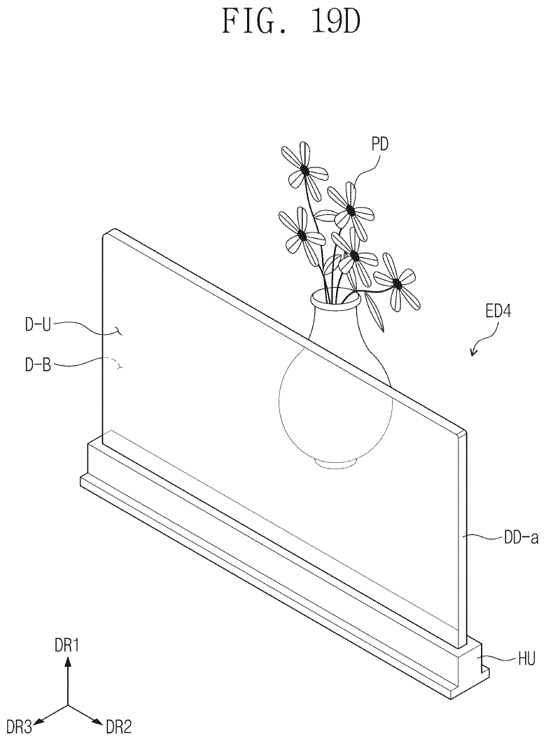

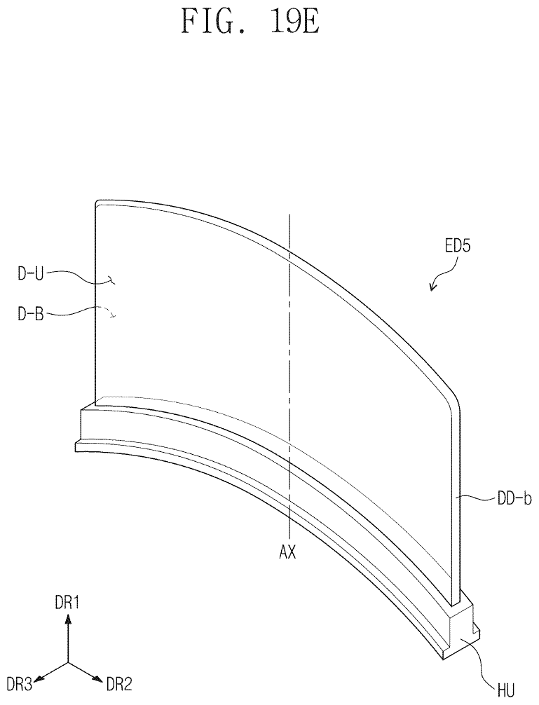

FIGS. 19A-19E are views illustrating electronic apparatuses to which a display device according to one or more embodiment of the present disclosure is applied. Hereinafter, electronic apparatuses ED1, ED2, ED3, ED4, and ED5, to which a display device according to one or more embodiments of the present disclosure is applied, will be described with reference to FIGS. 19A-19E.

FIG. 19A is a view illustrating a smart watch ED1 to which a display device DD1 according to one or more embodiments of the present disclosure is applied, and FIG. 19B is a view illustrating an eyeglasses-type virtual reality apparatus ED2 to which a display device DD2 according to one or more embodiments of the present disclosure is applied.

Referring to FIG. 19A, the smart watch ED1 may adopt the display device DD1 according to one or more embodiments, and the display device DD1 may have a structure explained in the descriptions made with reference to FIGS. 1-18G.

Referring to FIG. 19B, the virtual reality apparatus ED2 may include a left-eye lens, a right-eye lens, and a frame. The left-eye lens and the right-eye lens may each adopt the display device DD2 according to one or more embodiments, and the display device DD2 may have a structure illustrated in FIGS. 1-18G. Although the virtual reality apparatus ED2 including eyeglasses temples is illustrated in FIG. 19B as an example, the virtual reality apparatus ED2 according to one or more embodiments may be applied to a head mounted display including a head-mountable head mount band, in place of eyeglasses temples. The virtual reality apparatus ED2 according to one or more embodiments is not limited to a structure illustrated in the drawing, and is applicable to various electronic apparatuses in various forms in addition to the structure illustrated in the drawing.

Referring to FIG. 19C, a vehicular display ED3 may include first to fourth display devices DD-1, DD-2, DD-3, and DD-4 disposed inside a vehicle AM. At least one of the first to fourth display devices DD-1, DD-2, DD-3, or DD-4 may have a structure displayed in FIGS. 1-18G.

FIG. 19C illustrates a car for the vehicle AM, but this is an example, and the vehicular display ED3 may be disposed in other transportation devices such as a bicycle, a motorcycle, a train, a ship, an airplane, and/or the like.

Referring to FIG. 19C, the vehicle AM may include a handle HA and a gear GR for an operation of the vehicle AM. In addition, the vehicle AM may include a front window GL which is disposed to face the driver.

The first display device DD-1 may be disposed in a first region overlapping the handle HA. For example, the first display device DD-1 may be a digital cluster for displaying first information about the vehicle AM. The first information may include a first scale for showing the driving speed of the vehicle AM, a second scale for showing the rotational frequency of an engine (that is, revolutions per minute (RPM)), an image showing a fuel state, etc. The first scale and the second scale may be displayed in a digital image.

The second display device DD-2 may be disposed in a second region which faces the driver's seat and overlaps the front window GL. The driver's seat may be a seat where the handle HA is disposed. For example, the second display device DD-2 may be a head up display (HUD) for displaying second information about the vehicle AM. The second display device DD-2 may be optically transparent. The second information includes digital numbers showing the driving speed of the vehicle AM and may further include information such as current time. Unlike what is illustrated, the second information displayed on the second display device DD-2 may be displayed by being projected onto the front window GL.

The third display device DD-3 may be disposed in a third region adjacent to the gear GR. For example, the third display device DD-3 may be a center information display (CID) for vehicles which is disposed between the driver's seat and the passenger seat and which displays third information. The passenger seat may be a seat spaced (e.g., spaced apart) from the driver's seat with the gear GR therebetween. The third information may include information about road conditions (for example, navigation information), music or radio playback, a dynamic video (or an image) playback, inner temperature of the vehicle AM, etc.

The fourth display device DD-4 may be disposed in a fourth region adjacent to a side part of the vehicle AM and spaced (e.g., spaced apart) from the handle HA and the gear GR. For example, the fourth display device DD-4 may be a digital sideview mirror for displaying fourth information. The fourth display device DD-4 may display an external image of the vehicle AM captured by a camera module CM disposed on the outside of the vehicle AM. The fourth information may include an external image of the vehicle AM.

The aforementioned first to fourth information is an example, and the first to fourth display devices DD-1, DD-2, DD-3, and DD-4 may further display information about the inside and the outside of the vehicle AM. The first to fourth information may include different information. However, the present disclosure is not limited thereto, and some of the first to fourth information may include the same information.

Referring to FIGS. 19D and 19E, the electronic apparatuses ED4 and ED5 may include display devices DD-a and DD-b, and a housing HU for accommodating at least a portion of the display devices DD-a and DD-b. For example, a portion of a lower end of the display devices DD-a and DD-b may be accommodated in the housing HU. The electronic apparatuses ED4 and ED5 may adopt the display devices DD-a and DD-b according to one or more embodiments, and the display devices DD-a and DD-b may have a structure illustrated in FIGS. 1-18G.

The display devices DD-a and DD-b may display an image through a front surface D-U. An upper surface of a member disposed at the uppermost side of the display device DD-a may be defined as the front surface D-U of the display devices DD-a and DD-b.

In this embodiment, the front surface D-U is parallel to a plane defined by the first direction DR1 and the second direction DR2. A normal direction of the front surface D-U, that is, a thickness direction of the display device DD may be indicated by the third direction DR3.

The display devices DD-a and DD-b according to this embodiment may be a transparent display devices DD-a and DD-b. The transparent display devices DD-a and DD-b may display information while an object PD disposed to a rear surface D-B of the display devices DD-a and DD-b is clearly viewed on the front surface D-U of the display devices DD-a and DD-b. Thus, a user may recognize, on the front surface D-U of the display devices DD-a and DD-b, an object disposed to the rear surface D-B of the display devices DD-a and DD-b. Information is not limited to one of an image, content, a playback screen, an application execution screen, a web browser screen, various graphic objects, etc. FIG. 19D illustrates a vase as an example of the object PD, but the present disclosure is not limited thereto, and the object PD is not limited thereto as long as having a specific shape.

The housing HU may protect the display devices DD-a and DD-b from an external impact or infiltration of a foreign matter. The housing HU may be composed of materials such as plastic, metal, and/or the like. However, this is an example, and the present disclosure is not limited thereto, and any material may be used as long as being capable of protecting the display devices DD-a and DD-b from an external impact or infiltration of a foreign matter. The housing HU is omitted in the electronic apparatus ED according to one or more embodiments, but the display device DD may be rolled by a separate hinge member and disposed in the inside of the housing HU, and the present disclosure is not limited to any one embodiment.

Referring to FIG. 19E, the electronic apparatus ED5 according to one or more embodiments may be curved along the second direction DR2 with respect to a virtual axis AX extending in the first direction DR1. Thus, the display device DD-b may be curved to have a suitable curvature (e.g., a predetermined curvature), and the housing HU may have a corresponding curvature. However, the present disclosure is not limited thereto, and the axis may extend in the second direction DR2, or one or more embodiments of the present disclosure may be curved with respect to a plurality of axes extending in different directions.

In addition, the display devices DD-a and DD-b may be a rollable display panel, a foldable display panel, and/or a slidable display panel, and the display devices DD-a and DD-b may be disposed entirely inside the housing HU in one operation state. Accordingly, the display devices DD-a and DD-b may include a curved-type display surface or a three-dimensional display surface. The three-dimensional display surface may include a plurality of display regions indicating different directions.

A display device according to one or more embodiments has high resolution due to having a light-emitting diode stacked structure provided as a multilayer. The display device also includes common electrodes provided as multilayers and has a structure in which some light-emitting diodes disposed on different layers, from among the multilayered light-emitting diodes, are connected to different common electrodes. In addition, the common electrodes provided as multilayers may have a structure electrically connected to each other through an electrode pattern and thereby reduce the voltage drop that occurs in the common electrode. Accordingly, the resolution of the display device may be improved and defects may be reduced.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims to be described later. Therefore, the technical scope of the present disclosure is not to be limited to the contents stated in the detailed description of the specification, but may be determined by the claims and their equivalents.

What is claimed is:

1. A display device comprising:
a complementary metal oxide semiconductor (CMOS) wafer; and
a light-emitting structure layer on the CMOS wafer,
wherein the light-emitting structure layer comprises:
a first layer on the CMOS wafer and having a plurality of first light-emitting diodes configured to emit light of a first wavelength,
a second layer on the first layer and having a plurality of second light-emitting diodes configured to emit light of a second wavelength different from the first wavelength,
a third layer on the second layer and having a plurality of third light-emitting diodes configured to emit light of a third wavelength different from the first wavelength and the second wavelength,
a first common electrode connected to one or more of the plurality of first light-emitting diodes, the plurality of second light-emitting diodes, and the plurality of third light-emitting diodes,
a second common electrode connected to one or more of the rest of the plurality of first light-emitting diodes, the plurality of second light-emitting diodes, and the plurality of third light-emitting diodes, which are not connected to the first common electrode, and
an electrode pattern having a mesh structure on a plane, and electrically connecting the first common electrode and the second common electrode.

2. The display device of claim 1, wherein each of the plurality of first light-emitting diodes comprises a first light-emitting structure, a first lower conductive pattern under the first light-emitting structure, and a first upper conductive pattern on the first light-emitting structure,
wherein each of the plurality of second light-emitting diodes comprises a second light-emitting structure, a second lower conductive pattern under the second light-emitting structure, and a second upper conductive pattern on the second light-emitting structure,
wherein each of the plurality of third light-emitting diodes comprises a third light-emitting structure, a third lower conductive pattern under the third light-emitting structure, and a third upper conductive pattern on the third light-emitting structure,
wherein a planar area of the first lower conductive pattern is greater than or equal to a planar area of the first light-emitting structure,
wherein a planar area of the second lower conductive pattern is greater than or equal to a planar area of the second light-emitting structure, and
wherein a planar area of the third lower conductive pattern is greater than or equal to a planar area of the third light-emitting structure.

3. The display device of claim 2, wherein the first lower conductive pattern comprises at least one metal, and
wherein the second lower conductive pattern and the third lower conductive pattern each comprise a transparent conductive oxide.

4. The display device of claim 2, wherein the CMOS wafer comprises a silicon substrate, and a contact electrode on the silicon substrate, and
wherein each of the first lower conductive patterns of the plurality of first light-emitting diodes are in contact with the contact electrode.

5. The display device of claim 1, wherein at least a portion of each of the plurality of first light-emitting diodes does not overlap, on a plane, the plurality of second light-emitting diodes, and the third light-emitting diodes.

6. The display device of claim 1, wherein the light-emitting structure layer further comprises:
a plurality of first connection lines respectively overlapping the plurality of first light-emitting diodes, and electrically connected to the plurality of first light-emitting diodes, respectively;
a plurality of second connection lines respectively overlapping the plurality of second light-emitting diodes, and electrically connected to the plurality of second light-emitting diodes, respectively; and
a plurality of third connection lines respectively overlapping the plurality of third light-emitting diodes and electrically connected to the plurality of third light-emitting diodes, respectively.

7. The display device of claim 1, further comprising a plurality of lenses on the third layer and overlapping one or more of the plurality of first light-emitting diodes, the plurality of second light-emitting diodes, and the plurality of third light-emitting diodes.

8. The display device of claim 1, wherein a planar area of each of the plurality of second light-emitting diodes is greater than or equal to a planar area of each of the plurality of first light-emitting diodes, and
wherein a planar area of each of the plurality of third light-emitting diodes is greater than or equal to a planar area of each of the plurality of second light-emitting diodes.

9. The display device of claim 1, wherein a number of the plurality of second light-emitting diodes is twice a number of the plurality of first light-emitting diodes.

10. The display device of claim 1, wherein the first common electrode is on the second layer and connected to each of the plurality of first light-emitting diodes and each of the plurality of second light-emitting diodes,
wherein the second common electrode is on the third layer and connected to the plurality of third light-emitting diodes, and
wherein the electrode pattern and a portion of each of the plurality of third light-emitting diodes are at a same layer.

11. The display device of claim 1, wherein the light-emitting structure layer further comprises:
a third common electrode on the third layer and connected to the plurality of third light-emitting diodes; and
an additional electrode pattern having a mesh structure on a plane and within the third layer,
wherein the first common electrode is on the first layer and connected to the plurality of first light-emitting diodes,
wherein the second common electrode is on the second layer and connected to the plurality of second light-emitting diodes,
wherein the electrode pattern is within the second layer, and
wherein the additional electrode pattern electrically connects the second common electrode and the third common electrode.

12. The display device of claim 1, wherein the CMOS wafer comprises:
a first region in which the plurality of first light-emitting diodes, the plurality of second light-emitting diodes, and the plurality of third light-emitting diodes are located; and
a second region outside the first region on a plane,
wherein each of the first to third layers of the light-emitting structure layer further comprises a plurality of dummy light-emitting diodes in the second region, and
wherein the plurality of dummy light-emitting diodes do not emit light.

13. The display device of claim 12, wherein the electrode pattern comprises a first electrode pattern in the first region and a second electrode pattern in the second region, and
wherein the first common electrode and the second common electrode are electrically connected by the second electrode pattern.

14. The display device of claim 12, wherein the electrode pattern comprises a first electrode pattern in the first region and a second electrode pattern in the second region, and
wherein the first common electrode and the second common electrode are electrically connected by the first electrode pattern.

15. The display device of claim 1, wherein the light-emitting structure layer further comprises an optical layer comprising a plurality of first sub layers having a first refractive index and a plurality of second sub layers having a second refractive index different from the first refractive index, and
wherein the optical layer is located between the first layer and the second layer or between the second layer and the third layer.

16. The display device of claim 1, wherein the first layer further comprises at least a first planarization layer between the plurality of first light-emitting diodes,
wherein the second layer further comprises at least a second planarization layer between the plurality of second light-emitting diodes, and
wherein the third layer further comprises at least a third planarization layer between the plurality of third light-emitting diodes.

17. An electronic apparatus comprising:
a display device; and
a housing configured to accommodate the display device,
wherein the display device comprises:
a CMOS wafer; and
a light-emitting structure layer on the CMOS wafer,
wherein the light-emitting structure layer comprises:
a first layer on the CMOS wafer and having a plurality of first light-emitting diodes configured to emit light of a first wavelength;
a second layer on the first layer and having a plurality of second light-emitting diodes configured to emit light of a second wavelength different from the first wavelength;
a first common electrode connected to the plurality of first light-emitting diodes;
a second common electrode connected to the plurality of second light-emitting diodes; and
an electrode pattern electrically connecting the first common electrode and the second common electrode,
wherein each of the plurality of first light-emitting diodes comprises a first light-emitting structure, a first lower conductive pattern under the first light-emitting structure, and a first upper conductive pattern on the first light-emitting structure,
wherein each of the plurality of second light-emitting diodes comprises a second light-emitting structure, a second lower conductive pattern under the second light-emitting structure, and a second upper conductive pattern on the second light-emitting structure,
wherein the first common electrode is connected to the first upper conductive pattern, and
wherein the second common electrode is connected to the second upper conductive pattern.

18. A method for manufacturing a display device, the method comprising:
forming a first epitaxial layer on a CMOS wafer, and then forming a plurality of first light-emitting structures through patterning;
forming a second epitaxial layer on the plurality of first light-emitting structures, and then forming a plurality of second light-emitting structures through patterning;
forming a third epitaxial layer on the plurality of second light-emitting structures, and then forming a plurality of third light-emitting structures through patterning;
forming a first common electrode electrically connected to one or more of the plurality of first light-emitting structures, the plurality of second light-emitting structures, and the plurality of third light-emitting structures;
forming a second common electrode electrically connected to one or more of the rest of the plurality of first light-emitting structures, the plurality of second light-emitting structures, and the plurality of third light-emitting structures, which are not connected to the first common electrode; and
forming an electrode pattern having a mesh structure on a plane, and electrically connecting the first common electrode and the second common electrode.

19. The method of claim 18, wherein the first common electrode is electrically connected to each of the plurality of first light-emitting structures and each of the plurality of second light-emitting structures, and the second common electrode is electrically connected to the plurality of third light-emitting structures,
wherein the forming of the first common electrode is performed after forming the plurality of third light-emitting structures, and
wherein the forming of the second common electrode is performed after forming the first common electrode.

20. The method of claim 18, wherein in the forming of the plurality of first light-emitting structures, a first lower conductive layer is formed on the CMOS wafer before forming the first epitaxial layer,
wherein a plurality of first lower conductive patterns are formed by patterning the first lower conductive layer after the forming of the plurality of first light-emitting structures,
wherein the plurality of first light-emitting structures respectively overlaps the plurality of first lower conductive patterns, and
wherein a planar area of each of the plurality of first lower conductive patterns is greater than or equal to a planar area of each of the plurality of first light-emitting structures.
